(19) United States
(12) Patent Application Publication
(10) Pub. No.: US 2026/0311765 A1
(43) Pub. Date: Oct. 8, 2026

(54) SEMICONDUCTOR STRUCTURE, METHOD OF OPERATING THEREOF, AND SEMICONDUCTOR DEVICE

(71) Applicant: Yangtze Memory Technologies Holding Co., Ltd., Wuhan (CN)

(72) Inventors: Lei Jin, Wuhan (CN); Zongliang Huo, Wuhan (CN); Ziye Zhang, Wuhan (CN); Wendong Wang, Wuhan (CN); Yu Zhang, Wuhan (CN); Xinran Li, Wuhan (CN); Yuanyuan Min, Wuhan (CN); Feng Xu, Wuhan (CN)

(73) Assignee: Yangtze Memory Technologies Holding Co., Ltd., Wuhan (CN)

(21) Appl. No.: 19/434,950

(22) Filed: Dec. 29, 2025

(30) Foreign Application Priority Data
Apr. 3, 2025 (CN) 202510422700.8

(51) Int. Cl. G11C 16/10; G11C 16/08; G11C 16/28

(52) U.S. Cl. CPC G11C 16/102; G11C 16/08; G11C 16/28

(57) ABSTRACT

Examples of the present disclosure provide a semiconductor structure and a method of operating thereof, and a semiconductor device. The semiconductor structure includes a memory array configured to perform a first operation and a peripheral circuit coupled to the memory array; the memory array includes a memory string with a first end connected to a source line and a second end connected to a bit line; the memory string includes a plurality of memory cells and a plurality of dummy cells; the plurality of memory cells includes a first memory cell and a second memory cell; a first word line is coupled to the first memory cell; a second word line is coupled to the second memory cell; and a third word line is coupled to the plurality of dummy cells.

### CROSS-REFERENCE TO RELATED APPLICATIONS

This application claims the benefit of priority to Chinese Application No. 202510422700.8, filed on Apr. 3, 2025, which is hereby incorporated by reference in its entirety.

### TECHNICAL FIELD

Examples of the present disclosure relate to the field of semiconductor technology, in particular, to a semiconductor structure, a method of operating thereof, and a semiconductor device.

### BACKGROUND

In the classical Von Neumann computing architecture, the memory is separate from the processor, and data is transmitted through the data bus between them. When executing commands, the processor first reads the data from the memory, and then writes the updated data back into the memory, which brings significant power consumption and time overheads. In addition, since the memory bandwidth is limited, the processing speed of the processor is limited by the access speed of the memory, which has a significant impact on the calculation performance. With the rise of applications such as big data and artificial intelligence, the Von Neumann computing architecture has encountered its bottleneck under massive data processing.

### SUMMARY

In view of this, examples of the present disclosure provide a semiconductor structure, a method of operating thereof, and a semiconductor device.

In a first aspect, an example of the present disclosure provides a semiconductor structure including a memory array configured to perform a first operation and a peripheral circuit coupled to the memory array; the memory array includes a memory string; a first end of the memory string is connected to a source line, and a second end of the memory string is connected to a bit line; the memory string includes a plurality of memory cells and a plurality of dummy cells; the plurality of memory cells include a first memory cell and a second memory cell; a first word line is coupled to the first memory cell; a second word line is coupled to the second memory cell; a third word line is coupled to the plurality of dummy cells; and the peripheral circuit is configured to: perform a first program operation on the first memory cell; perform a second program operation on the plurality of dummy cells; apply a first pass voltage to the second word line; apply a second pass voltage different from the first pass voltage to the third word line; and obtain a first current passing through the memory string.

In some examples, the peripheral circuit is configured to: complete the second program operation when the first current is less than a first preset value.

In some examples, the peripheral circuit is configured to: increase the program voltage of the second program operation according to the first current being greater than or equal to the first preset value and continue to perform the second program operation; continue to apply a first pass voltage to the second word line and apply a second pass voltage to the third word line to obtain the corresponding first current; and complete the second program operation when the first current is less than the first preset value.

In some examples, the peripheral circuit is configured to: apply a program voltage, during performing the first program operation, to the first word line by applying a plurality of first step pulse voltages; a difference between two adjacent ones of first step pulse voltages is a first step length voltage; apply a program voltage, during performing the second program operation, to the third word line by applying a plurality of second step pulse voltages; a difference between two adjacent second step pulse voltages is a second step length voltage, where a pulse width of the second step pulse voltage is less than a pulse width of the first step pulse voltage, or the second step length voltage is less than the first step length voltage.

In some examples, the peripheral circuit is further configured to: apply a read voltage to the first word line, apply a first pass voltage to the second word line, and apply a first operating voltage less than the second pass voltage to the third word line during performing a reading operation on the memory cell coupled with the first word line, such that the plurality of dummy cells operate in a linear region.

In some examples, the peripheral circuit is further configured to: perform a first program operation, where the memory cell coupled to the first word line has a first threshold voltage; perform a second program operation, where one of the plurality of dummy cells has a second threshold voltage that is greater than the first threshold voltage; apply a read voltage to the first word line, apply a first pass voltage to the second word line, and apply a second operating voltage to the third word line during performing a reading operation on the memory cell coupled to the first word line, where the second operating voltage is less than the first pass voltage.

In some examples, the peripheral circuit is further configured to: apply a read voltage to the first word line, apply a third pass voltage to the second word line, and apply a third operating voltage to the third word line during performing a first reading operation on the memory cell coupled with the first word line, according to the memory cell coupled with the first word line being at a first position in the memory string; apply a read voltage to the first word line, apply a fourth pass voltage to the second word line, and apply a third operating voltage to the third word line during performing a second reading operation on the memory cell coupled with the first word line, according to the memory cell coupled with the first word line being at a second position in the memory string, where the first position is closer to the bit line than the second position, and the third pass voltage is greater than the fourth pass voltage.

In some examples, the plurality of dummy cells include: a bottom dummy cell between the source line and the plurality of memory cells, or a top dummy cell between the bit line and the plurality of memory cells.

In some examples, a plurality of memory strings located in the same column have a first end connected to a source line and a second end connected to a bit line; the first word line is coupled to corresponding memory cells in a plurality of memory strings located in the same column; and the peripheral circuit is further configured to: perform a reading operation on corresponding memory cells coupled to the first word line, obtain a second current passing through the bit line, and obtain a result of the first operation based on the second current.

In some examples, the third word line includes a first portion and a plurality of second portions connected to the first portion; a first end of each second portion is connected to a gate terminal of a corresponding dummy cell; and a second end of each second portion is commonly connected to the first portion, where the first portion is configured to receive the second pass voltage.

In a second aspect, an example of the present disclosure provides a semiconductor structure including a memory array configured to perform a first operation and a peripheral circuit coupled to the memory array; the memory array includes a memory string; a first end of the memory string is connected to the source line, and a second end of the memory string is connected to the bit line; the memory string includes a plurality of memory cells and a plurality of dummy cells, where the plurality of memory cells are coupled to a plurality of first gate layers; the plurality of dummy cells are coupled to the plurality of second gate layers; the first ends of the plurality of second gate layers are coupled to the plurality of dummy cells, respectively and the second ends of the plurality of second gate layers commonly contact and are electrically connected to the connection structure; the connection structure includes a conductive material.

In some examples, the plurality of dummy cells include: a bottom dummy cell between the source line and the plurality of memory cells, or a top dummy cell between the bit line and the plurality of memory cells.

In some examples, a plurality of memory strings located in the same column have a first end connected to a source line and a second end connected to a bit line, and the first gate layers are coupled to corresponding memory cells in a plurality of memory strings located in the same column.

In a third aspect, an example of the present disclosure provides a semiconductor structure, including: a stack structure including a gate layer and an insulating layer spaced apart with each other, where the stack structure includes a plurality of gate layers including a plurality of first gate layers and a plurality of second gate layers; a memory structure extending through the stack structure and including a plurality of memory cells coupled to the first gate layers and a plurality of dummy cells coupled to the second gate layers; and a connection structure including a conductive material and being in contact with and electrically connected to the plurality of second gate layers.

In some examples, the connection structure includes: a first connection line located over the stack structure; a plurality of first contact structures with first ends extending and connected to the second gate layers, respectively, and second ends commonly connected to the first connection line; or, a second contact structure with a first end extending through at least some of the plurality of second gate layers and connected to the plurality of second gate layers and a second end connected to the first connection line.

In some examples, the plurality of second gate layers include: a bottom second gate layer at the bottom of the stack structure, or a top second gate layer on top of the stack structure.

According to a fourth aspect, an example of the present disclosure provides a semiconductor device, including: any one of one or more of the semiconductor structures provided in first aspect, any one of the semiconductor structures provided in the second aspect, or any one of the semiconductor structures provided in the third aspect; and a processing circuit bonded to the semiconductor structure and configured to convert analog calculation information obtained by the first operation performed by the semiconductor structure into digital information, and perform a second operation on the digital information, where the analog calculation information includes a first current passing through the memory string of the semiconductor structure.

In some examples, the processing circuit includes an analog-to-digital conversion circuit and a data processing circuit; the analog-to-digital conversion circuit is configured to convert the analog calculation information into digital information; and the data processing circuit is configured to perform the second operation on the digital information.

In some examples, the processing circuit further includes a first interface circuit and a controller; the first interface circuit is configured to output an operation result of the second operation performed by the digital processing circuit to an external device; and the controller is configured to control the semiconductor structure to perform the first operation.

In some examples, the first operation includes a multiply-accumulate operation.

In some examples, the second operation includes one or more of compensation, activation, shift, or pooling operations.

In a fifth aspect, an example of the present disclosure provides a method of operating a semiconductor structure, including: performing a first program operation on a memory cell of a plurality of memory cells of the semiconductor structure coupled with a first word line; performing a second program operation on a plurality of dummy cells of the semiconductor structure; applying a first pass voltage to the second word line; applying a second pass voltage different from the first pass voltage to the third word line; and obtaining a first current passing through a memory string, where the semiconductor structure includes a memory array configured to perform a first operation and a peripheral circuit coupled with the memory array; the memory array includes a memory string; a first end of the memory string is connected to a source line, and a second end of the memory string is connected to a bit line; the memory string includes a plurality of memory cells and a plurality of dummy cells; the plurality of memory cells include a first memory cell and a second memory cell; the first word line is coupled to the first memory cell, the second word line is coupled to the second memory cell; and the third word line is coupled to the plurality of dummy cells.

In some examples, the method includes: completing the second program operation when the first current is less than a first preset value.

In some examples, the method includes: increasing a program voltage of the second program operation according to the first current being greater than or equal to the first preset value and continuing to perform the second program operation; and continuing to apply the first pass voltage to the second word line and applying the second pass voltage to the third word line to obtain a corresponding first current; completing the second program operation when the first current is less than the first preset value.

In some examples, the method includes: applying a program voltage, during performing the first program operation, to the first word line by applying a plurality of first step pulse voltages, where a difference between two adjacent ones of first step pulse voltages is a first step length voltage; applying a program voltage to the third word line by applying a plurality of second step pulse voltages during performing the second program operation, where a difference between two adjacent second step pulse voltages is a second step length voltage, where a pulse width of the second step pulse voltage is less than a pulse width of the first step pulse voltage, or the second step length voltage is less than the first step length voltage.

In some examples, the method further includes: applying a read voltage to the first word line, applying a first pass voltage to the second word line, and applying a first operating voltage less than the second pass voltage to the third word line during performing a reading operation on the memory cell coupled with the first word line, such that the plurality of dummy cells operate in a linear region.

In some examples, the method further includes: performing a first program operation, where the memory cell coupled to the first word line has a first threshold voltage; performing a second program operation, where one of the plurality of dummy cells has a second threshold voltage that is greater than the first threshold voltage; applying a read voltage to the first word line, applying a first pass voltage to the second word line, and applying a second operating voltage to the third word line during performing a reading operation on the memory cell coupled to the first word line, where the second operating voltage is less than the first pass voltage.

In some examples, the method further includes: applying a read voltage to the first word line, applying a third pass voltage to the second word line, and applying a third operating voltage to the third word line during performing a first reading operation on the memory cell coupled with the first word line, according to the memory cell coupled with the first word line being at a first position in the memory string; applying a read voltage to the first word line, applying a fourth pass voltage to the second word line, and applying a third operating voltage to the third word line during performing a second reading operation on the memory cell coupled with the first word line, according to the memory cell coupled with the first word line being at a second position in the memory string, where the first position is closer to the bit line than the second position, and the third pass voltage is greater than the fourth pass voltage.

In some examples, the plurality of dummy cells include: a bottom dummy cell between the source line and the plurality of memory cells, or a top dummy cell between the bit line and the plurality of memory cells.

In some examples, the method further includes: performing a reading operation on corresponding memory cells located in the same column and coupled to the first word line, obtaining a second current passing through the bit line, and determining a result of the first operation based on the second current, where the plurality of memory strings located in the same column have a first end connected to the source line and a second end connected to the bit line; and the first word line is coupled to corresponding memory cells in a plurality of memory strings located in the same column.

In some examples, the third word line includes a first portion and a plurality of second portions connected to the first portion; a first end of each second portion is connected to a gate terminal of a corresponding dummy cell; and a second end of each second portion is commonly connected to the first portion, where the first portion is configured to receive the second pass voltage.

In the examples of the present disclosure, the memory string includes a plurality of dummy cells, and the dummy cells are programmed to a non-erasing program state. When the memory string is in a turned-on state, the equivalent resistance corresponding to the dummy cell can avoid or mitigate the impact of the equivalent resistance corresponding to the memory cell coupled with the non-selected word line on the current on the bit line, and when the selected word line is located at different positions, the current variation on the corresponding bit line is zero or relatively small, thus the current consistency on the bit line in the process of performing the first operation can be improved, and the error rate in the process of performing the first operation is reduced or eliminated.

### BRIEF DESCRIPTION OF THE DRAWINGS

FIG. 1 is a schematic diagram of a semiconductor structure provided by an example of the present disclosure;

FIG. 2 is a first schematic diagram of a semiconductor structure including a peripheral circuit and a memory array provided by an example of the present disclosure;

FIG. 3 is a second schematic diagram of a semiconductor structure including a peripheral circuit and a memory array provided by an example of the present disclosure;

FIG. 4 is a third schematic diagram of a semiconductor structure including a peripheral circuit and a memory array provided by an example of the present disclosure;

FIG. 5 is a cross-sectional schematic diagram of a memory array including a memory string provided by an example of the present disclosure;

FIG. 6 is a distribution schematic diagram of a memory array of a semiconductor structure provided by an example of the present disclosure;

FIG. 7 is a distribution schematic diagram of memory blocks of a memory array provided by an example of the present disclosure;

FIG. 8 is a distribution schematic diagram of a memory string of a memory block provided by an example of the present disclosure;

FIG. 9A is a schematic diagram of a memory block storing a weight by a memory cell corresponding to a target word line, inputting an input voltage by a top select gate line, and outputting an output current by a bit line provided by an example of the present disclosure;

FIG. 9B is a schematic diagram of forming a binary multiplication operation on a weight stored in a memory cell of a memory string and an input voltage input by a top select gate line of a corresponding memory string provided by an example of the present disclosure;

FIG. 9C is a schematic diagram of reading a weight stored in a memory cell corresponding to a target word line provided by an example of the present disclosure;

FIG. 10 is a schematic diagram of a plurality of memory strings coupled with a bit line provided by an example of the present disclosure;

FIG. 11 is a first schematic diagram of a memory string with a first end connected to a source line and a second end connected to a bit line provided by an example of the present disclosure;

FIG. 12 is an equivalent circuit schematic diagram of the memory string of FIG. 11;

FIG. 13 is a schematic diagram of a current-voltage characteristic curve of a target word line of the memory string of FIG. 11 at different positions;

FIG. 14 is a second schematic diagram of a memory string with a first end connected to a source line and a second end connected to a bit line provided by an example of the present disclosure;

FIG. 15 is an equivalent circuit schematic diagram of the memory string of FIG. 14;

FIG. 16 is a schematic diagram of a current-voltage characteristic curve of a target word line of the memory string of FIG. 14 at different positions;

FIG. 17 is a third schematic diagram of a memory string with a first end connected to a source line and a second end connected to a bit line provided by an example of the present disclosure;

FIG. 18 is a schematic diagram of a current-voltage characteristic curve of the dummy word lines of the memory string of FIG. 17 in different program states;

FIG. 19 is a schematic flowchart of programming a dummy cell of the memory string of FIG. 17;

FIG. 20A is a waveform schematic diagram of performing an erasing operation on the memory cell and the dummy cell of the memory string in FIG. 17;

FIG. 20B is a waveform schematic diagram of the erasing operation verification of FIG. 20A;

FIG. 20C is a waveform schematic diagram of performing a program operation on a memory cell of the memory string of FIG. 17;

FIG. 20D is a waveform schematic diagram of the program operation verification of FIG. 20C;

FIG. 20E is a waveform schematic diagram of performing a program operation on a dummy cell of the memory string of FIG. 17;

FIG. 20F is a waveform schematic diagram of the program operation verification of FIG. 20E;

FIG. 20G is a waveform schematic diagram of performing a reading operation on a memory cell of the memory string of FIG. 17;

FIG. 20H is a schematic diagram of comparison between a threshold voltage distribution of a memory cell in an erase state/program state and a threshold voltage distribution of a dummy cell in a program state provided by an example of the present disclosure;

FIG. 21 is a fourth schematic diagram of a memory string with a first end connected to a source line and a second end connected to a bit line provided by an example of the present disclosure;

FIG. 22 is a schematic diagram of a current-voltage characteristic curve of the dummy word lines of the memory string of FIG. 21 in different program states;

FIG. 23 is a schematic flowchart of programming a dummy cell of the memory string of FIG. 21;

FIG. 24 is a schematic diagram of some memory strings with a first end connected to a source line and a second end connected to a bit line provided by an example of the present disclosure;

FIG. 25 is a schematic diagram of memory strings commonly connected to a connection structure of a plurality of dummy word lines coupled with a plurality of dummy cells provided by an example of the present disclosure;

FIG. 26 is a first cross-sectional schematic diagram of a semiconductor structure including a connection structure provided by an example of the present disclosure;

FIG. 27 is a second cross-sectional schematic diagram of a semiconductor structure including a connection structure provided by an example of the present disclosure;

FIG. 28 is a structural schematic diagram of a semiconductor device provided by an example of the present disclosure;

FIG. 29 is a schematic diagram of an example system having a computing-in-memory device provided by an example of the present disclosure; and

FIG. 30 is a schematic flowchart of a method of operating a semiconductor structure provided by an example of the present disclosure.

### DETAILED DESCRIPTION

The technical solutions in the implementations of the present disclosure will be clearly and completely described below with reference to the implementations of the present disclosure and the accompanying drawings, and it is obvious that the described examples are only a part, but not all of the examples of the present disclosure. All other examples obtained by those skilled in the art without creative efforts shall fall within the scope of the present disclosure.

In the following description, numerous details are given in order to provide a more thorough understanding of the present disclosure. However, it will be apparent to one skilled in the art that, the present disclosure may be practiced without one or more of these details. In other examples, in order to avoid confusion with the present disclosure, some technical features known in the art are not described; that is, not all features of the actual examples are described here, and well-known functions and structures are not described in detail.

In the drawings, the sizes of layers, regions, elements, and their relative sizes may be exaggerated for clarity. Like reference numbers refer to like elements throughout the specification.

It should be appreciated that when an element or layer is referred to as being “on,” “adjacent to,” “connected to” or “coupled to” other elements or layers, it may be directly on, adjacent to, connected to, or coupled to other elements or layers, or intervening elements or layers may be present. Conversely, when an element is referred to as being “directly on,” “directly adjacent,” “directly connected to,” or “directly coupled to” other elements or layers, there is no intervening element or layer. It should be appreciated that although the terms first, second, third, etc. may be used to describe at least one of various elements, components, regions, layers, portions, at least one of these elements, components, regions, layers, portions should not be limited by these terms. These terms are used merely to distinguish one element, component, region, layer, or portion from another element, component, region, layer, or portion. Thus, the first element, component, region, layer, or portion discussed below may be represented as a second element, component, region, layer, or portion without departing from the teachings of the present disclosure. However, when the second component, component, region, layer or portion is discussed, it does not indicate that the first element, component, region, layer or portion is necessarily present in the present disclosure.

Spatial relationship terms such as “under,” “below,” “lower,” “beneath,” “over,” “above,” etc., may be used herein for ease of description to describe the relationship between one element or feature and other elements or features shown in the figures. It should be appreciated that, in addition to the orientations shown in the figures, the spatial relation terms intend to also comprise different orientations of the devices in use and operation. For example, if the devices in the figures are flipped over, then those described as “below” or “under” or “beneath” other elements or features will be oriented “on” other elements or features. Thus, the example terms “below” and “beneath” may comprise both upper and lower orientations. The devices may be additionally oriented (rotated 90 degrees or other orientations) and the spatial description terminology used herein is interpreted accordingly.

The terms used herein are for the purpose of describing a particular example only and are not to be considered as limitation of the present disclosure. As used herein, “a,” “an” and “the” in the singular form are intended to comprise the plural forms as well, unless the context indicated clearly otherwise. It should also be understood that the terms “consist of” or “comprising,” when used in this description, indicate the presence of the stated features, integers, steps, operations, elements or components, but do not exclude the presence and addition of one or more other features, integers, steps, operations, elements, components or groups. As used herein, the term “and/or” comprises any and all combinations of the related listed items.

For a thorough understanding of the present disclosure, detailed steps and detailed structures will be presented in the following description to explain the technical solutions of the present disclosure. Some examples of the present disclosure are described in detail below, however, other examples may be provided in addition to these detailed description.

With the rise of applications such as big data and artificial intelligence, the Von Neumann computing architecture has encountered its bottleneck under massive data processing. In order to overcome the bottleneck of the Von Neumann computing architecture, a computing-in-memory (CIM) chip architecture emerges. Its basic principle is to embed a calculation function in the memory, and directly use the memory to perform logic calculation, thereby reducing the amount of data transmission and the transmission distance between the memory and the processor, reducing the power consumption while improving the calculation performance, and yields a computing system with improved computation power, bandwidth, and energy efficiency.

The computing-in-memory chip have both storage and computation capabilities based on its own physical characteristics. The storage capability refers to the capability of different memories to achieve a stored value by changing their conductance according to their physical characteristics, and the computing capability refers to the capability to complete the vector matrix multiplication calculation within a certain time by constructing an array composed of memory devices, according to Ohm's law and Kirchhoff's law. The computing-in-memory chip includes, but is not limited to, Static Random Access Memory (SRAM), NAND flash memory, and Dynamic Random Access Memory (DRAM). NAND flash memory is a non-volatile memory and has a relatively large capacity, and thus has become an object of interest in the computing-in-memory chip. The related description of the NAND flash memory will be provided below accordingly.

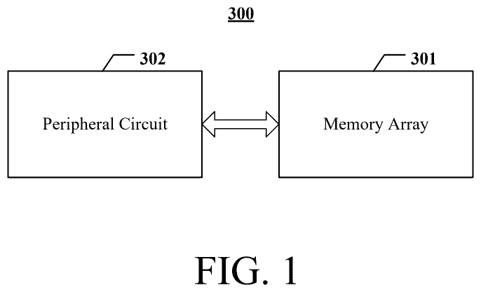

FIG. 1 is a schematic diagram of a semiconductor structure provided by an example of the present disclosure. Referring to FIG. 1, the semiconductor structure 300 includes a memory array 301 configured to perform a first operation and a peripheral circuit 302 coupled to the memory array 301. In some examples, the semiconductor structure includes a first semiconductor structure (not shown in FIG. 1) and a second semiconductor structure (not shown in FIG. 1) stacked together. The first semiconductor structure may include a memory array and a portion of the peripheral circuit of the semiconductor structure. The second semiconductor structure may include another portion of the peripheral circuit of the semiconductor structure, e.g., a portion of the peripheral circuit of the semiconductor structure is formed in the first semiconductor structure, and another portion is formed in the second semiconductor structure. For example, in the example of the present disclosure, a page buffer in the peripheral circuit may be formed on the first semiconductor structure. In some other examples, the semiconductor structure includes a first semiconductor structure and a second semiconductor structure stacked together, a memory array of the semiconductor structure is formed in the first semiconductor structure, and a peripheral circuit of the semiconductor structure is formed in the second semiconductor structure.

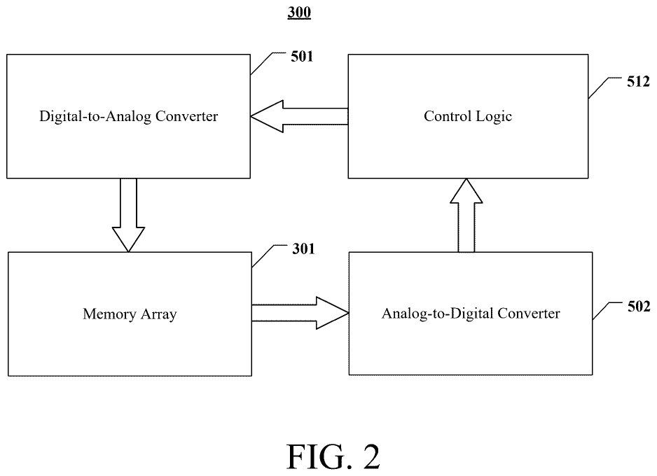

FIG. 2 is a first schematic diagram of a semiconductor structure including a peripheral circuit and a memory array provided by an example of the present disclosure. Referring to FIG. 1 and FIG. 2, the peripheral circuit 302 may include a control logic 512, a digital-to-analog converter 501 coupled with the control logic 512 and the memory array 301, and an analog-to-digital converter 502 coupled with the memory array 301 and the control logic 512. When performing the first operation with the semiconductor structure, the digital-to-analog converter 501 may convert the digital signal into a voltage signal required by the memory array 301 in the semiconductor structure. The analog-to-digital converter 502 may convert a current signal output by the memory array 301 into a digital signal. The control logic 512 may be coupled to the peripheral circuit and configured to control operation of the peripheral circuit. The control logic 512 may be further configured to receive input data sent by an external device. Here, the digital-to-analog converter 501 is a one-bit DAC, and the analog-to-digital converter 502 is a one-bit ADC.

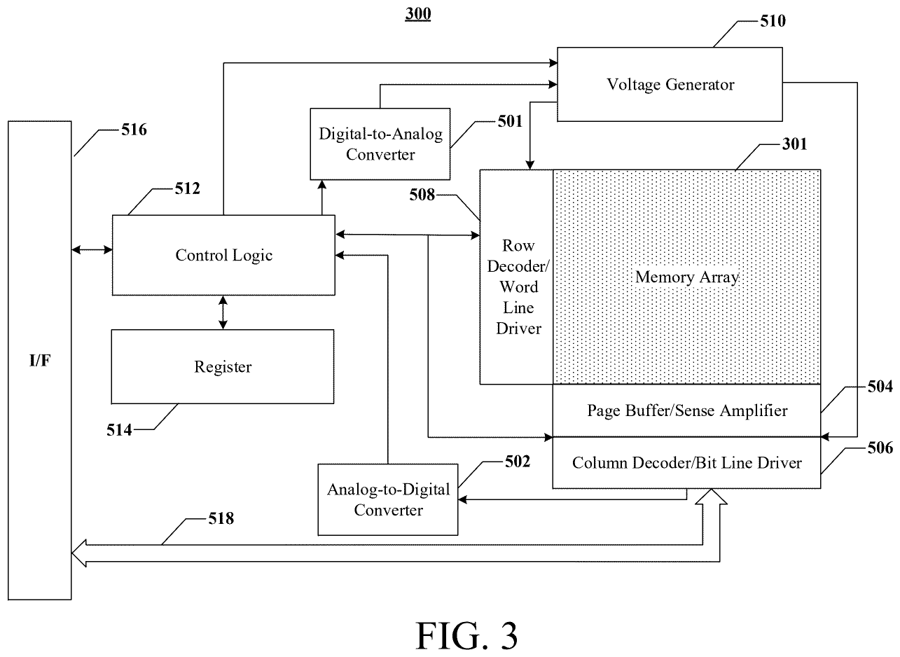

FIG. 3 is a second schematic diagram of a semiconductor structure including a peripheral circuit and a memory array provided by an example of the present disclosure. Referring to FIG. 1, FIG. 2 and FIG. 3, in addition to the circuit structure shown in FIG. 2, the peripheral circuit 302 may also include a page buffer/sense amplifier 504, a column decoder/bit line driver 506, a row decoder/word line driver 508, a voltage generator 510, a register 514, and a data bus 518. It should be understood that in some examples, additional peripheral circuits not shown in FIG. 2 and FIG. 3 may also be included.

As shown in FIG. 3, the control logic 512 may be coupled to other circuit structures other than the control logic 512 in the peripheral circuit described above, and configured to control operation of peripheral circuit. The registers 514 may be coupled to the control logic 512 and include status registers, command registers, and address registers for storing status information, command op-codes (OP codes), and command addresses for controlling operation of each peripheral circuit.

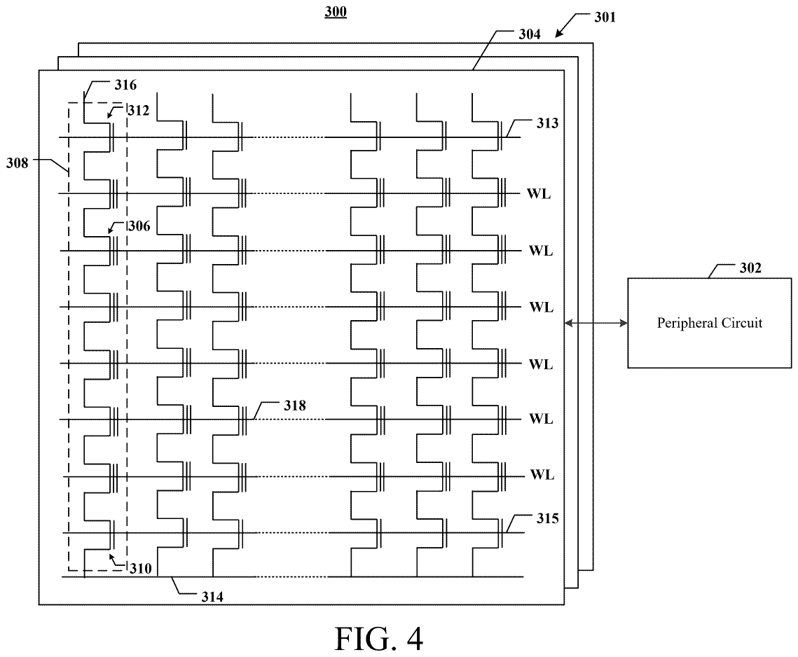

As shown in FIG. 3 and FIG. 4, the page buffer/sense amplifier 504 may be configured to read data from and program (write) data to the memory array 301 according to control signals from the control logic 512. In one example, the page buffer/sense amplifier 504 may store program data (write data) to be programmed to the memory cells 306 of the memory array 301. In another example, the page buffer/sense amplifier 504 may perform a program-verify operation to ensure that the data has been correctly programmed into the memory cell 306 coupled to the target word line 318. Column decoder/bit line driver 506 may be configured to be controlled by the control logic 512 and select one or more NAND memory strings 308 by applying a bit line voltage obtained from the voltage generator 510.

As shown in FIG. 3 and FIG. 4, the row decoder/word line driver 508 may be configured to be controlled by the control logic 512 and select or deselect the memory block 304 of the memory array 301 and select or deselect the word line 318 of the memory block 304. The row decoder/word line driver 508 may also be configured to drive the word line 318 using the word line voltage obtained from the voltage generator 510. In some implementations, row decoder/word line driver 508 may also select or deselect and drive Bottom Select Gate line (BSG) 315 and Top Select Gate line (TSG) 313. As described in detail below, the row decoder/word line driver 508 is configured to perform a program operation on the memory cells 306 coupled to the target word line(s) 318. The voltage generator 510 may be configured to be controlled by the control logic 512 and obtain word line voltages (e.g., read voltages, program voltages, pass voltages, local voltages, verify voltages, input voltages, etc.), bit line voltages, and source line voltages to be supplied to the memory array 301.

FIG. 4 is a third schematic diagram of a semiconductor structure including a peripheral circuit and a memory array provided by an example of the present disclosure. Referring to FIG. 1 and FIG. 4, a semiconductor structure 300 may include a memory array 301 and a peripheral circuit 302 coupled to the memory array 301. Taking the memory array 301 as a three-dimensional NAND type memory array as an example for description, the memory cell 306 is a NAND memory cell, the memory cell 306 is provided in the form of an array of memory strings 308, and each memory string 308 extends vertically. In some examples, each memory string 308 includes a plurality of memory cells 306 coupled in series and stacked vertically. Each memory cell 306 may maintain a continuous analog value, e.g., voltage or charge, depending on the number of electrons captured within the area of the memory cell 306. Each memory cell 306 may be a floating-gate-type memory cell including a floating-gate transistor, or a charge-trapping-type memory cell including a charge-trapping transistor.

In some examples, each memory cell 306 is a Single Level Cell (SLC) having two possible memory states and thus may store one bit of data. For example, the first memory state “0” may correspond to a first voltage range and the second memory state “1” may correspond to a second voltage range. In some examples, each memory cell 306 is a Multi-Level Cell (MLC) capable of storing more than a single bit of data in four or more memory states, e.g., a MLC storing two bits per cell, a Triple Level Cell (TLC) storing three bits per cell, or a Quad-Level Cell (QLC) storing four bits per cell.

As shown in FIG. 4, each memory string 308 may include a bottom select transistor 310 at its source terminal and a top select transistor 312 at its drain terminal. The bottom select transistor 310 and the top select transistor 312 may be configured to activate the selected memory string 308 during read and program operations. In some examples, the source terminals of the memory strings 308 in the same memory block 304 may be coupled through a Common Source Line (CSL) 314. In other words, all memory strings 308 in the same memory block 304 have an Array Common Source (ACS) (also referred to herein as a source line or common source line). According to some examples, the top select transistor 312 of each memory string 308 is coupled to a corresponding bit line 316, and data may be read from or written into the bit line 316 via an output bus (not shown). In some examples, each memory string 308 is configured to be selected or deselected by applying a select voltage (e.g., a voltage higher than a threshold voltage of the top select transistor 312) or a deselect voltage (e.g., 0V) to the corresponding top select transistor 312 through one or more top select gate lines 313 and/or applying a select voltage (e.g., a voltage above a threshold voltage of the bottom select transistor 310) or a deselect voltage (e.g., 0V) to the corresponding bottom select transistor 310 through one or more bottom select gate lines 315.

As shown in FIG. 4, the memory string 308 may be organized into a plurality of memory blocks 304, each of which may have a common source line 314. In some examples, each memory block 304 is a basic data unit for an erasing operation, e.g., all memory cells 306 on the same memory block 304 are erased simultaneously. To erase the memory cells 306 in the selected memory block, a common source line 314 coupled to the selected memory block and an unselected memory block in the same plane as the selected memory block may be biased with an erase voltage. It should be understood that in some examples, the erasing operation may be performed at half memory block level, at quarter memory block level, or memory blocks with any suitable number or at any suitable fractional level of memory blocks. Memory cells 306 of adjacent memory strings 308 may be coupled by word lines 318 that select a row of memory cells 306 for read or program operations.

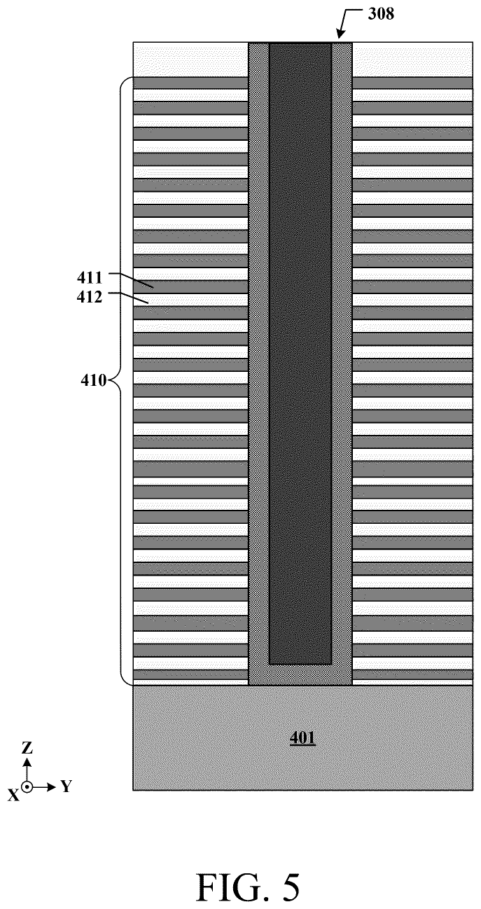

FIG. 5 is a cross-sectional schematic diagram of a memory array including a memory string provided by an example of the present disclosure. As shown in FIG. 5, a stack structure 410 includes a plurality of gate layers 411 and a plurality of insulating layers 412 stacked alternately in sequence, and a memory string 308 vertically extending through the gate layer 411 and the insulating layer 412. The gate layer 411 and the insulating layer 412 may be stacked alternately, and two adjacent gate layers 411 are separated by an insulating layer 412. The number of memory cells included in the memory array is mainly related to the number of pairs of gate layers 411 and insulating layers 412 in the stack structure 410.

The composition material of the gate layer 411 may include a conductive material. The conductive material includes, but is not limited to, tungsten (W), cobalt (Co), copper (Cu), aluminum (Al), polysilicon, doped silicon, silicide, or any combination thereof. In some examples, each gate layer 411 includes a metal layer, such as a tungsten layer. In some examples, each gate layer 411 includes a doped polysilicon layer. Each gate layer 411 may include a control gate surrounding the memory cell. The gate layer 411 at the top of the stack structure 410 may extend laterally as a top select gate line, the gate layer 411 at the bottom of the stack structure 410 may extend laterally as a bottom select gate line, and the gate layer 411 extending laterally between the top select gate line and the bottom select gate line may serve as a word line.

In some examples, the stack structure 410 may be disposed on the semiconductor layer 401. The semiconductor layer 401 may include silicon (e.g., monocrystalline silicon), silicon germanium (SiGe), gallium arsenide (GaAs), germanium (Ge), silicon-on-insulator (SOI), germanium-on-insulator (GOI), or any other suitable material. In other examples, the semiconductor device may not include the semiconductor layer.

In some examples, the memory string 308 includes a channel structure that extends vertically through the stack structure 410. In some examples, the channel structure includes a channel hole filled with semiconductor material(s) (e.g., as a semiconductor channel) and dielectric material(s) (e.g., as a memory film). In some examples, the semiconductor channel includes silicon, e.g., polysilicon. In some examples, the memory film is a composite dielectric layer including a tunneling layer, a storage layer (also referred to as a “charge trapping or storage layer”), and a blocking layer. The channel structure may have a cylindrical shape (e.g., a pillar shape). According to some examples, the semiconductor channel, the tunneling layer, the storage layer, and the blocking layer are arranged radially from the center of the pillar toward the outer surface of the pillar in this order. The tunneling layer may include silicon oxide, silicon oxynitride, or any combination thereof. The storage layer may include silicon nitride, silicon oxynitride, or any combination thereof. The blocking layer may include silicon oxide, silicon oxynitride, a high-k dielectric, or any combination thereof. In one example, the memory film may include a composite layer of silicon oxide/silicon oxynitride/silicon oxide (ONO).

Referring back to FIG. 4, the peripheral circuit 302 may be coupled to the memory array 301 through bit lines 316, word lines 318, source lines 314, bottom select gate lines 315, and top select gate lines 313. The peripheral circuit 302 may include any suitable analog, digital, and mixed-signal circuit for facilitating operation of the memory array 301 by applying at least one of voltage signals and current signals to and sensing at least one of voltage signals and current signals from each of the target memory cells 306 via bit lines 316, word lines 318, source lines 314, bottom select gate lines 315, and top select gate lines 313. Peripheral circuit 302 may include various types of peripheral circuit formed by metal-oxide-semiconductor technology.

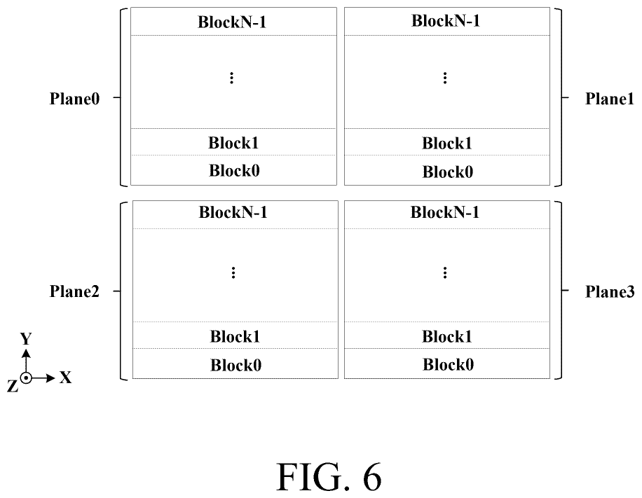

FIG. 6 is a distribution schematic diagram of a memory array of a semiconductor structure provided by an example of the present disclosure. Referring to FIG. 6, an example in which the semiconductor structure is a three-dimensional NAND type memory is described. Here and below, a first direction is parallel to the direction in which the word lines extend; a second direction is parallel to the direction in which the bit lines extend, the first direction and the second direction intersects (e.g., are perpendicular); a third direction is parallel to the direction in which the memory strings extend. For example, the first direction is perpendicular to the second direction, the third direction is perpendicular to both the first direction and the second direction, the first direction may be the X direction in the figure, the second direction may be the Y direction in the figure, and the third direction may be the Z direction in the figure.

As shown in FIG. 6, the memory array may include a plurality of memory planes, for example, the memory array includes 4 memory planes: memory plane Plane0, memory plane Plane1, memory plane Plane2, and memory plane Plane3. Each memory plane includes a plurality of memory banks, and each memory bank includes a plurality of memory blocks, for example, the memory plane Plane0 includes N memory blocks of the memory block Block0, the memory blocks Block1, . . . , and the memory block BlockN−1, where N is a natural number. In an alternative example, the number of memory planes in the memory array may be less than 4 (e.g., 2) or more than 4 (e.g., 5).

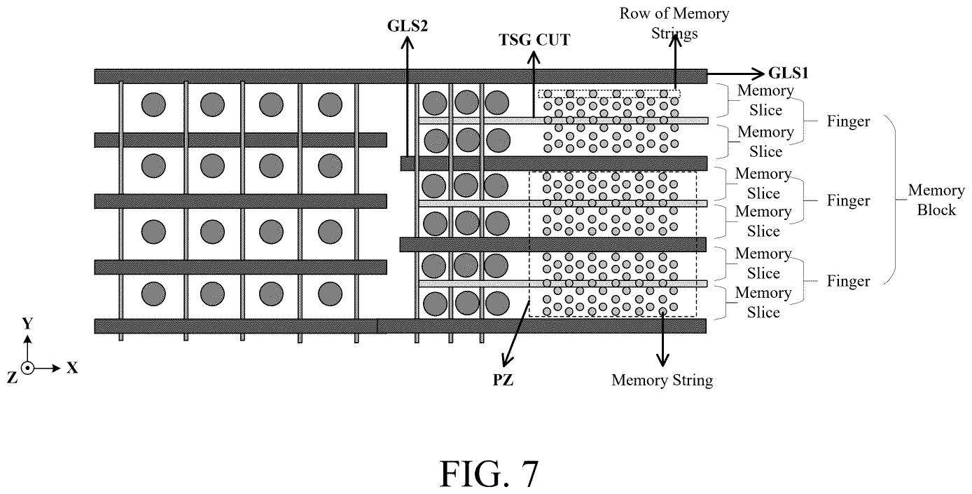

FIG. 7 is a distribution schematic diagram of memory blocks of a memory array provided by an example of the present disclosure. Referring to FIG. 7, a memory array is composed of a plurality of rows of memory strings staggered in parallel (regarded as a row of memory strings arranged in a row direction) parallel to a Gate Line Slit (GLS), each four rows of memory strings are divided by a gate line slit and a select gate line slit, each memory string row includes a plurality of memory strings arranged along the X direction, one memory cell in each memory string is shown in FIG. 7, and the remaining memory cells and the one memory cell are arranged along the Z direction.

Referring to FIG. 7, the select gate line slit may be a top select gate line slit TSG CUT, and the top select gate line slit TSG CUT divides the top select gate TSG into a plurality of top select gate lines. The select gate line slit may also be a bottom select gate line slit BSG CUT (not shown in FIG. 7) that divides the bottom select gate BSG (not shown in FIG. 7) into a plurality of bottom select gate lines. The gate line slit may include a first gate line slit GLS1 and a second gate line slit GLS2, the first gate line slit GLS1 divides the memory array into a plurality of memory blocks, the plurality of second gate line slits GLS2 may divide the memory block into a plurality of fingers, and the select gate line slit disposed in the middle of each finger may divide the finger into two parts, thereby dividing the finger into two slices. In actual application, the number of fingers included in one memory block may be adjusted according to actual conditions, such as 2, 3, 4, 5, and the like. In practical applications, the number of slices included in one memory block may be adjusted according to actual conditions, such as 2, 4, 6, 8, 10, 12, 14, and 16. FIG. 7 shows only one memory block of the memory, but the memory may include a plurality of memory blocks. As shown in FIG. 7, adjacent memory blocks are separated by the first gate line slit GLS1, and the plurality of memory blocks may be arranged along the Y direction.

It should be noted that the number of rows of memory strings between the gate line slit and the select gate line slit given in FIG. 7 is merely an example, and is not intended to limit the number of memory strings included in one finger of the three-dimensional NAND type memory in the present disclosure. In actual application, the number of memory string rows included in one finger may be adjusted according to actual conditions, for example, may be 2, 4, 8, and 16.

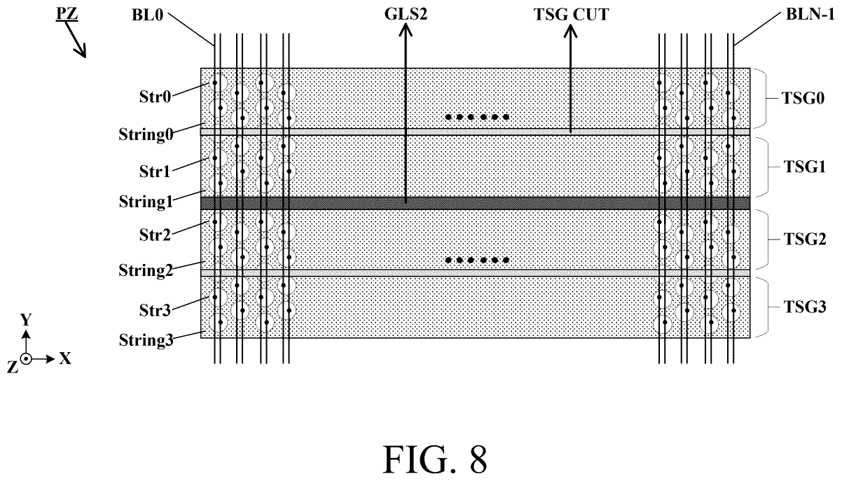

FIG. 8 is a distribution schematic diagram of a memory string of a memory array provided by an example of the present disclosure. FIG. 8 may be regarded as an enlarged schematic diagram of the region PZ of FIG. 7, and shows the bit line and the second end of the memory string that is connected to the bit line. As shown in FIG. 8, the second gate line slit GLS2 and the top select gate line slit TSG CUT divide the memory block into a plurality of slices, such as 6 slices (four slices are shown in FIG. 8, namely, String0, String1, String2, and String3), different slices may be selected by the corresponding top select gate TSG, e.g., String0, String1, String2, and String3 may be selected or deselected by the top select gate TSG0, the top select gate TSG 1, the top select gate TSG 2, and the top select gate TSG 3, respectively.

As shown in FIG. 8, a first end of a memory string of the memory array is connected to a source line (or an array common source), and its second end is connected to a bit line. The slice includes a plurality of memory strings Str0, and second ends of the plurality of memory strings Str0 are connected to corresponding bit lines, respectively for example, N different memory strings Str0 in the slice are connected to the bit line BL0 to the bit line BLN−1 respectively. Along the extending direction of the bit line, each bit line is connected to a memory string in a different slice String0, for example, the bit line BL0 is connected to the second end of the memory string Str0 of String0, the memory string Str1 of String1, the memory string Str2 of String2, and the memory string Str3 of String 3.

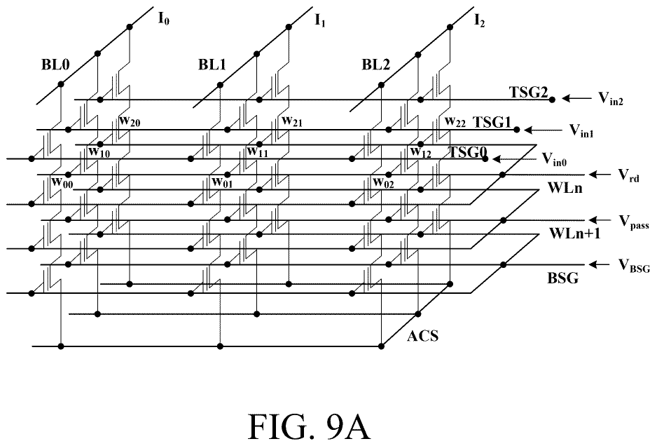

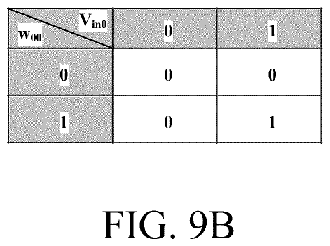

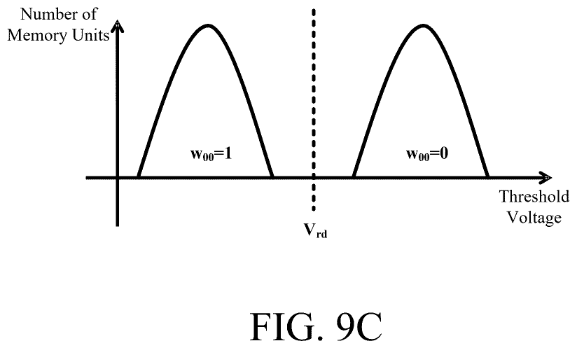

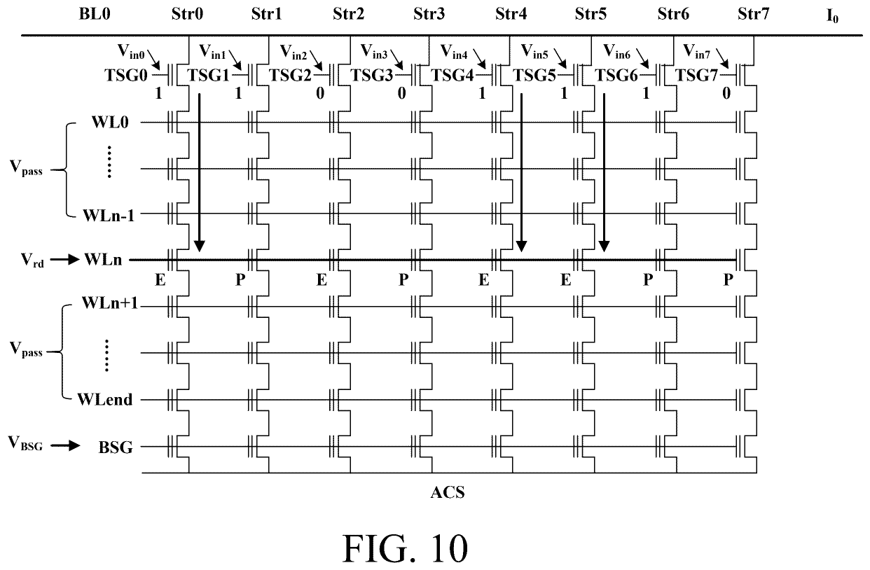

FIG. 9A is a schematic diagram of a memory block storing a weight by a memory cell corresponding to a target word line, inputting an input voltage by a top select gate line, and outputting an output current by a bit line provided by an example of the present disclosure. FIG. 9B is a schematic diagram of forming a binary multiplication operation on a weight stored in a memory cell of a memory string and an input voltage input by a top select gate line of a corresponding memory string provided by an example of the present disclosure. FIG. 9C is a schematic diagram of reading a weight stored in a memory cell corresponding to a target word line provided by an example of the present disclosure. FIG. 10 is a schematic diagram of a plurality of memory strings coupled with a bit line provided by an example of the present disclosure. It should be noted that the number of the bit lines shown in FIG. 9A and FIG. 10, the number of the memory strings coupled to each bit line, and the number of the memory cells in each memory string are merely examples, and the specific number of the structures is not limited in the present disclosure.

The following describes a specific process of the first operation by taking the bit line as an analog signal output terminal as an example.

As shown in FIG. 9A, after the first operation stage by using the memory array, the peripheral circuit is configured to: apply a first read voltage V_{rd} to the target word line WLn coupled to the target memory block, and apply a corresponding input voltage, respectively, to a plurality of top select gate lines coupled to the target memory block, for example, the input voltages Vᵢₙ₀, Vᵢₙ₁, Vᵢₙ₂ may be applied, respectively, to the top select gate lines TSG0, TSG1, and TSG2 coupled to the target memory block. The pass voltage Vₚₐₛₛ may be applied to the non-target word line coupled to the target memory block, for example, the pass voltage Vₚₐₛₛ may be applied to the word line WLn+1 to turn on the memory cell coupled to the non-target word line. The pass voltage V_{BSG} is applied to the bottom select gate line coupled to the target memory block, for example, the pass voltage V_{BSG} may be applied to the bottom select gate line BSG to turn on the bottom select transistor. The analog calculation information may be obtained by sensing the current on the bit line coupled to the target memory block, for example, the analog calculation information may be obtained by sensing the current I₀, I₁ and I₂ on the bit lines BL0, BL1 and BL2.

As shown in FIG. 9B and FIG. 9C, the input voltage Vᵢₙ₀ is received from the top select gate line TSG0 coupled to the target memory block. The input voltage Vᵢₙ₀ causes the top select transistor to be turned on, the element corresponding to the input voltage Vᵢₙ₀ is the logic “1;” the input voltage Vᵢₙ₀ causes the top select transistor to be turned off, and the element corresponding to the input voltage Vᵢₙ₀ is a logic “0.” The weight woo is stored in the target memory cell in the memory string coupled to the top select gate line TSG0, the read voltage V_{rd} is received by the target word line coupled to the target memory cell, the read voltage V_{rd} causes the target memory cell to be turned on, the readout weight woo is the logic “1,” the read voltage V_{rd} causes the target memory cell to be turned off, and the readout weight woo is a logic “0.”

With continued reference to FIG. 9A, by sensing the current I₀ on the bit line BL0 and converting the current I₀, the sum of the product of the element corresponding to the input voltage Vᵢₙ₀ and the weight woo, the product of the element corresponding to the input voltage Vᵢₙ₁ and the weight w₁₀, and the product of the element corresponding to the input voltage Vᵢₙ₂ and the weight w₂₀ is obtained, e.g., sensing the current on the bit line BL0 I₀=Vᵢₙ₀*w₀₀+Vᵢₙ₁*w₁₀+Vᵢₙ₂*w₂₀. Similarly, it can be obtained that sensing the current on the bit line BL2 I₁=Vᵢₙ₀*w₀₁+Vᵢₙ₁*w₁₁+Vᵢₙ₂*w₂₁ and sensing the current on the bit line BL2 I₂=Vᵢₙ₀*w₀₂+Vᵢₙ₁*w₁₂+Vᵢₙ₂*w₂₂. As such, sensing the current I_{y} on the bit line BLy satisfies the following formula (1):

$${I}_{y} = \sum {V}_{inx} * {w}_{xy} = {V}_{in 0} * {w}_{00} + {V}_{in 1} * {w}_{10} + … {V}_{inx} * {w}_{x 0} \qquad ( 1 )$$

In the formula (1), (x+1) represents the number of memory strings connected to one bit line in the target memory block performing the first operation, and (y+1) represents the number of bit lines in the target memory block performing the first operation. In some examples, the first operation includes a multiply-accumulate operation.

As shown in FIG. 10, in some examples, taking the target memory block including eight memory strings (memory strings Str0 to Str7) coupled to the bit line BL0 as an example, four memory cells in the eight memory cells coupled to the target word line WLn are in a first memory state (erase state E), the other four memory cells are in a second memory state (program state P), and the input data may be input from eight top select gate lines TSG0 to TSG7. For instance, the input data may be an input vector including eight elements which may include five “1” and three “0.” The digital-to-analog conversion circuit may convert each element of the input vector to a corresponding voltage signal, and convert the voltage signal into an input voltage that needs to be applied to the top select gate line through the voltage generator, and transfer the input voltage to the top select gate line through a driver coupled to the top select gate line. For instance, eight input voltages may be applied to eight top select gate lines, respectively. The input voltages corresponding to “1” include Vᵢₙ₀, Vᵢₙ₁, Vᵢₙ₄, Vᵢₙ₅, and Vᵢₙ₆, so that the top select transistors coupled to the top select gate lines TSG0, TSG 1, TSG 4, TSG 5 and TSG 6, respectively, are turned on, and the input voltages corresponding to “zero” include Vᵢₙ₂, Vᵢₙ₃, Vᵢₙ₇, and the top select transistors coupled to the top select gate lines TSG 2, TSG 3 and TSG 7, respectively, are turned off.

As shown in FIG. 10, in some examples, the current I₀ on the bit line BL0 is the sum of the output currents of the eight memory strings coupled to the bit line BL0, where the input voltage on the top select gate line coupled to the memory strings Str0, Str1, Str4, Str5 and Str6 causes the top select transistors coupled to the top select gate lines TSG 0, TSG 1, TSG 4, TSG 5 and TSG 6 to be in the turned-on state, and the eight memory cells in the memory strings Str0 to Str7 that are coupled to the target word line WLn have the first memory state (erase state E), the second memory state (program state P), the erase state E, the program state P, the erase state E, the erase state E, the program state P, and the program state P, respectively. The input voltage on the top select gate line coupled to the memory strings Str0, Str4, and Str5 causes the top select transistors coupled to the top select gate lines TSG0, TSG4, and TSG5 to be in the turned-on state, and the memory cells in the memory strings Str0, Str4, and Str5 coupled to the target word line WLn have the first memory state (erase state E), so that the memory strings Str0, Str4, and Str5 are turned on, and a current greater than or equal to a preset current may be generated. The current I₀ on the bit line BL0 and the sum of the output currents of the memory strings Str0, Str4, and Str5 are substantially equal, and a multiple of the current I₀ with respect to any one of the memory strings Str0, Str4 and Str5 is approximately equal to three. If the weight value stored in the memory cell in the first memory state is equivalent to “1” and the weight value stored in the memory cell in the second memory state is equivalent to “0,” the operations performed by the eight memory strings coupled to the bit line BL0 may be equivalent to: 1*1+1*0+0*1+0*0+1*1+1*1+1*0+0*0=3, where the operation result “3” is represented by a decimal number, while the operation result may also be represented by a binary number, for example, represented by a two-bit binary number “10.”

Based on the above example, when there are y memory strings in the target memory block coupled to the bit line BLx, the y elements corresponding to the input voltage input by the y first selection line are α₀, α₁, . . . , α_{y-1}, and the weights stored in the y memory cells coupled to the target word line WLn are w₀, w₁, . . . , w_{y-1} respectively, and the analog calculation information equivalent to the multiple of the current I_{y} on the bit line BLy relative to the output current greater than or equal to the preset current may satisfy the formula I_{y}=α₀*w₀+α₁*w₁+ . . . +α_{y-1}*w_{y-1}.

In some examples, the peripheral circuit may be configured to: apply a first read voltage V_{rd}, respectively, to the target word lines correspondingly coupled to the plurality of memory blocks of the memory bank; apply a pass voltage Vₚₐₛₛ to the non-target word lines in the plurality of memory banks; apply a corresponding input voltage Vᵢₙ₀~V_{inN}, respectively, to the plurality of top select gate lines correspondingly coupled to the plurality of memory blocks of the memory bank; and sense the current I₀~I_{y} on the bit lines coupled to the plurality of memory blocks of the memory bank. In some examples, the first read voltage V_{rd} may be applied simultaneously to the target word lines correspondingly coupled to the plurality of memory blocks Block0~BlockN in the memory bank, the corresponding input voltages Vᵢₙ₀~V_{inN} are applied simultaneously to the plurality of top select gate lines correspondingly coupled to the plurality of memory blocks Block0~BlockN, the current on the bit lines coupled to the plurality of memory blocks Block0~BlockN is sensed, and the current I₀~I_{y} on the bit lines BL0~BLy is the analog calculation information after the first operation is performed on all memory strings coupled to the bit line. Therefore, the plurality of memory blocks can perform the first operation in parallel, so that the operation efficiency and the computing power of the semiconductor device can be further improved.

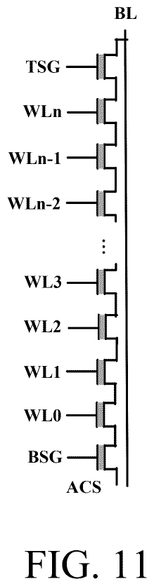

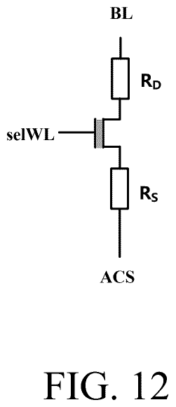

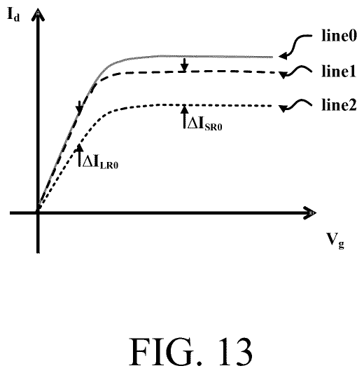

FIG. 11 is a first schematic diagram of a memory string with a first end connected to a source line and a second end connected to a bit line provided by an example of the present disclosure. FIG. 12 is an equivalent circuit schematic diagram of the memory string of FIG. 11. FIG. 13 is a schematic diagram of a current-voltage characteristic curve of a target word line of the memory string of FIG. 11 at different positions.

Referring to FIG. 11, the memory string includes a plurality of memory cells, the number of the plurality of memory cells is (n+1), n is a natural number greater than 1, and each memory cell is coupled to a corresponding word line WL0, a word line WL1, a word line WL2, a word line WL3, . . . , a word line WLn−2, a word line WLn−1, and a word line WLn, respectively. The first ends of the plurality of memory cells are coupled to the source line ACS through the bottom select transistors, the second ends of the plurality of memory cells are coupled to the bit line BL through the top select transistors, a gate terminal of the top select transistor is connected to the top select gate line TSG, and a gate terminal of the bottom select transistor is connected to the bottom select gate line BSG.

Referring to FIG. 12, when the memory string is in a turned-on state, the equivalent resistance corresponding to the memory cell between the selected memory cell (the memory cell coupled to the selected word line selWL) and the source line ACS is the first equivalent resistance R_{S}, and the equivalent resistance corresponding to the memory cell between the selected memory cell and the bit line BL is the second equivalent resistance R_{D}. It should be noted that, in the following description, in the equivalent circuit diagram of the memory string between the bit line BL and the source line ACS, the impact of the equivalent resistance of the bottom select transistor and the top select transistor may be ignored, or the equivalent resistance of the bottom selection transistor and the top selection transistor may be considered as a fixed value.

FIG. 13 shows the characteristic curve of the current I_{d} on the bit line BL and the gate voltage V_{g} received from the selected word line selWL when the memory string is in a turned-on state. The curve line0 may be regarded as a current-voltage characteristic curve measured when the memory cells of the memory string are all in an erase state. The curve line1 may be regarded as a current-voltage characteristic curve measured when at least part of the memory cells of the memory string are in a program state, where the selected word line selWL is a word line close to the source line ACS, such as word line WL2. The curve line2 may be regarded as a current-voltage characteristic curve measured when at least part of the memory cells of the memory string are in a program state, where the selected word line selWL is a word line close to the bit line BL, such as the word line WLn−2.

With reference to FIG. 11, FIG. 12, and FIG. 13, when the memory string is in a turned-on state (e.g., when the selected word lines are located at different positions, the non-selected word lines are applied with the same pass voltage), compared with the case that the selected word line selWL is the word line close to the bit line BL (e.g., the selected word line selWL is the word line WLn−2, corresponding to the curve line2 of FIG. 13), when the selected word line selWL is the word line close to the source line ACS (e.g., the selected word line selWL is the word line WL2, corresponding to the curve line1 of FIG. 13), the sum of the first equivalent resistance R_{S} and the second equivalent resistance R_{D} is relatively small, and the current I_{d} on the bit line BL is relatively large. As shown in FIG. 13, the current difference ΔI_{LR0} of the curve line1 and the curve line2 in the linear region is relatively large, and the current difference ΔI_{SR0} of the curve line1 and the curve line2 in the saturation region is relatively large.

The memory string is configured that during performing the first operation, the current on the bit line needs to be sensed, and there is a high requirement on the current variation on the bit line BL (e.g., the current variation is required to be relatively small). Therefore, when the target word lines (the selected word lines) are located at different positions, the equivalent resistance of the memory cell coupled with the non-selected word line is different, which has a large impact on the current variation on the bit line. Since the target word lines (the selected word lines) are located at different positions, the current variation on the corresponding bit line is relatively large, which is not conducive to improving the current consistency of the bit line in the process of performing the first operation, and also not conducive to reducing or eliminating the error rate in the process of performing the first operation.

In view of this, examples of the present disclosure provide a semiconductor structure, a method of operating thereof, and a semiconductor device.

In a first aspect, an example of the present disclosure provides a semiconductor structure including a memory array configured to perform a first operation and a peripheral circuit coupled to the memory array; the memory array includes a memory string; a first end of the memory string is connected to a source line, and a second end of the memory string is connected to the bit line; the memory string includes a plurality of memory cells and a plurality of dummy cells; the plurality of memory cells include a first memory cell and a second memory cell; a first word line is coupled to the first memory cell, and a second word line is coupled to the second memory cell; a third word line is coupled to the plurality of dummy cells; the peripheral circuit configured to: perform a first program operation on the first memory cell; perform a second program operation on the plurality of dummy cells; apply a first pass voltage to the second word line; apply a second pass voltage different from the first pass voltage to the third word line; and obtain a first current passing through the memory string.

In the example of the present disclosure, the memory string includes a plurality of dummy cells and the dummy cells are programmed to a non-erasing program state. When the memory string is in a turned-on state, the equivalent resistance corresponding to the dummy cell can avoid or reduce the impact of the equivalent resistance corresponding to the memory cell coupled with the non-selected word line on the current on the bit line, and when the selected word lines are located at different positions, the current variation on the corresponding bit line is zero or relatively small, which may improve the current consistency on the bit line in the process of performing the first operation, and reduce or eliminate the error rate in the process of executing the first operation.

Here and below, the memory array and the peripheral circuit of the semiconductor structure may be understood with reference to the related description of FIG. 1 to FIG. 10, and details are not described herein again. The semiconductor structure is configured to perform the first operation, it is also beneficial to replace some of the memory cells of the memory string with a plurality of dummy cells, and the dummy cells may be programmed to a non-erasing program state. A part of the memory cells of the memory string may be set as a dummy cell not configured to store the weight by a manner of software setting, or the dummy cell not configured to store the weight may be disposed in the memory string in the manufacturing process of the semiconductor structure by a manner of hardware setting.

Here and below, the first word line may be regarded as a target word line or a selected word line in word lines coupled to the plurality of memory cells, and the first memory cell may be regarded as a memory cell coupled to the target word line or the selected word line. The second word line may be regarded as a non-target word line or a non-selected word line of the word lines coupled to the plurality of memory cells, and the second memory cell may be regarded as a memory cell coupled to the non-target word line or the non-selected word line. The third word line may be regarded as including a plurality of dummy word lines coupled to a plurality of dummy cells, each dummy word line has a first end connected to a gate terminal of a respective dummy cell and a second end coupled to a respective row decoder/word line driver, and each dummy word line of the plurality of dummy word lines may separately receive a driving circuit (e.g., a second pass voltage). Alternatively, the third word line may be regarded as including a first portion and a plurality of second portions connected to the first portion; a first end of each second portion is connected to a gate terminal of a corresponding one of the dummy cells; a second end of each second portion is commonly connected to a first end of the first portion, where a second end of the first portion is connected to a corresponding row decoder/word line driver, and a second end of the first portion is configured to receive a driving circuit (e.g., a second pass voltage).

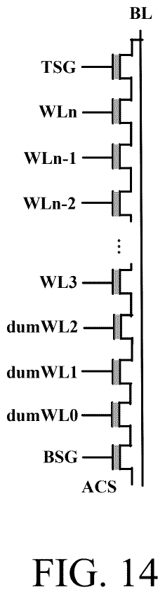

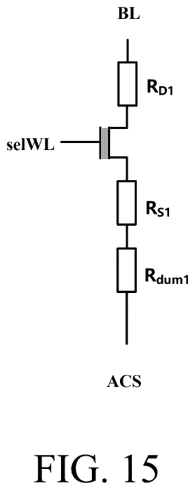

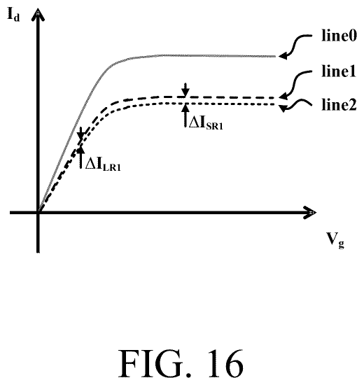

FIG. 14 is a second schematic diagram of a memory string with a first end connected to a source line and a second end connected to a bit line provided by an example of the present disclosure. FIG. 15 is an equivalent circuit schematic diagram of the memory string of FIG. 14. FIG. 16 is a schematic diagram of a current-voltage characteristic curve of a target word line of the memory string of FIG. 14 at different positions. It should be noted that the memory string shown in FIG. 14 may be regarded as setting two or more memory cells in the memory string shown in FIG. 11 as dummy cells not configured for storing weights, and word lines coupled with dummy cells are dummy word lines.

Referring to FIG. 14, the memory string includes a plurality of memory cells and a plurality of dummy cells, the number of the plurality of memory cells is (n−2), n is a natural number greater than 2, each memory cell is coupled to a corresponding word line WL3, . . . , a word line WLn−2, a word line WLn−1, and a word line WLn respectively, the number of the plurality of dummy cells is 3, and each dummy cell is coupled to a corresponding dummy word line dumWL0, a dummy word line dumWL1, and a dummy word line dumWL2 respectively. The plurality of memory cells and the plurality of dummy cells are coupled to the bit line BL through the top select transistor, and are coupled to the source line ACS through the bottom select transistor. The gate terminal of the top select transistor is connected to the top select gate line TSG, and the gate terminal of the bottom select transistor is connected to the bottom select gate line BSG.

Referring to FIG. 15, when the memory string is in a turned-on state, the equivalent resistance corresponding to the memory cell between the selected memory cell (the memory cell coupled to the selected word line selWL) and the source line ACS is the first equivalent resistance R_{S1}, the equivalent resistance corresponding to the dummy cell located between the selected memory cell and the source line ACS is the third equivalent resistance R_{dum1}, and the equivalent resistance corresponding to the memory cell between the selected memory cell and the bit line BL is the second equivalent resistance R_{D1}.

Referring to FIG. 16, FIG. 16 shows a current-voltage characteristic curve of the current I_{d} on the bit line BL and the gate voltage V_{g} received from the selected word line selWL when the memory string is in a turned-on state. The curve line0 may be regarded as a current-voltage characteristic curve measured when the memory cells of the memory string are all in an erase state. The curve line1 may be regarded as a current-voltage characteristic curve measured when at least part of the memory cells of the memory string are in a program state, where the selected word line selWL is a word line close to the source line ACS, such as word line WL2. The curve line2 may be regarded as a current-voltage characteristic curve measured when at least part of the memory cells of the memory string are in a program state, where the selected word line selWL is a word line close to the bit line BL, such as the word line WLn−2.

With reference to FIG. 14, FIG. 15 and FIG. 16, compared with the current difference ΔI_{LR0} in the linear region shown in FIG. 13, the current difference ΔI_{LR1} in the linear region between the curve line1 and the curve line2 shown in FIG. 16 is smaller, e.g., the current difference ΔI_{LR1} is less than the current difference ΔI_{LR0}. Compared with the current difference ΔI_{SR0} in the linear region shown in FIG. 13, the current difference ΔI_{SR1} in the saturation region between the curve line1 and the curve line2 shown in FIG. 16 is smaller, e.g., the current difference ΔI_{SR1} is less than the current difference ΔI_{SR0}.

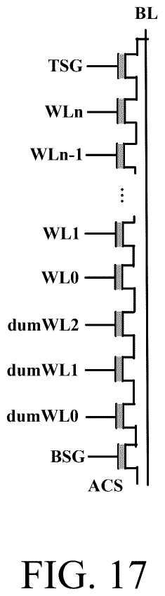

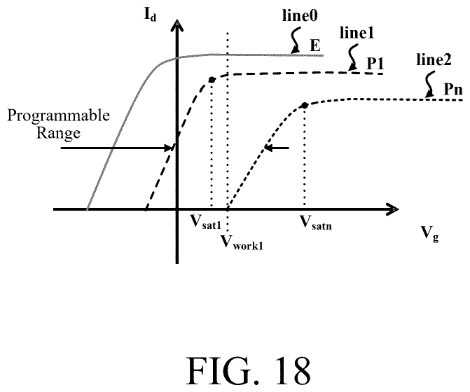

FIG. 17 is a third schematic diagram of a memory string with a first end connected to a source line and a second end connected to a bit line provided by an example of the present disclosure. FIG. 18 is a schematic diagram of a current-voltage characteristic curve of the dummy word lines of the memory string of FIG. 17 in different program states. It should be noted that the memory string shown in FIG. 17 may be regarded as the memory string shown in FIG. 14, and here, for convenience of description, compared with the memory string shown in FIG. 14, the word lines coupled to the memory cell shown in FIG. 17 are sequentially numbered as word line WL0, word line WL1, . . . , word line WLn−1 and word line WLn, and the dummy word lines coupled to the dummy cell shown in FIG. 17 are sequentially numbered as dummy word line dumWL0, dummy word line dumWL1, . . . , and so on.

Referring to FIG. 17, a first end of a memory string is connected to a source line ACS, a second end is connected to a bit line BL, and a memory string includes a plurality of memory cells and a plurality of dummy cells. The number of the plurality of memory cells is (n+1), n is a natural number, and each memory cell is coupled to a corresponding word line WL0, word line WL1, . . . , word line WLn−2, word line WLn−1, and word line WLn respectively. The number of the plurality of dummy cells is 3, and the each dummy cell is coupled to the corresponding dummy word line dumWL0, dummy word line dumWL1 and dummy word line dumWL2 respectively. In an alternative example, the number of the plurality of dummy cells may be 2 or greater than 3 (e.g., 4, 5, or 6). As such, by setting a larger number of dummy cells, the current consistency on the bit line in the process of performing the first operation may be improved, the error rate in the process of performing the first operation may be reduced or eliminated. On the other hand, setting a larger number of dummy cells may also reduce the storage capacity of the semiconductor structure, and therefore, there needs a trade-off due to the relationship between the current consistency and the storage capacity, and an appropriate number of dummy cells may be set as 2, 4 or 6.

FIG. 18 shows a current-voltage characteristic curve of the current I_{d} on the bit line BL and the gate voltage V_{g} received from the plurality of dummy word lines dumWL when the memory string is in a turned-on state. The curve line0 may be regarded as the current-voltage characteristic curve measured when the plurality of dummy cells of the memory string are all in the erase state E. The curve line1 may be regarded as the current-voltage characteristic curve measured when the plurality of dummy cells of the memory string are in the first program state P1. The curve line2 may be regarded as the current-voltage characteristic curve measured when the plurality of dummy cells of the memory string are in the nth program state Pn. Compared with the plurality of dummy cells being in the first program state P1, when the plurality of dummy cells are in the nth program state Pn, the equivalent resistance of the plurality of dummy cells in an operating state is larger, so that the current I_{d} on the bit line BL is smaller. The programmable range of the plurality of dummy cells can be regarded as the threshold voltage range between the minimum threshold voltage of the first program state P1 and the maximum threshold voltage of the nth program state Pn. The semiconductor structure is configured to perform a first operation, and further needs to apply a pass voltage to a plurality of dummy word lines, where the pass voltage is greater than a maximum threshold voltage of a program state in which the plurality of dummy cells are, so as to turn on the plurality of dummy cells, and the plurality of dummy cells are in an operating state.

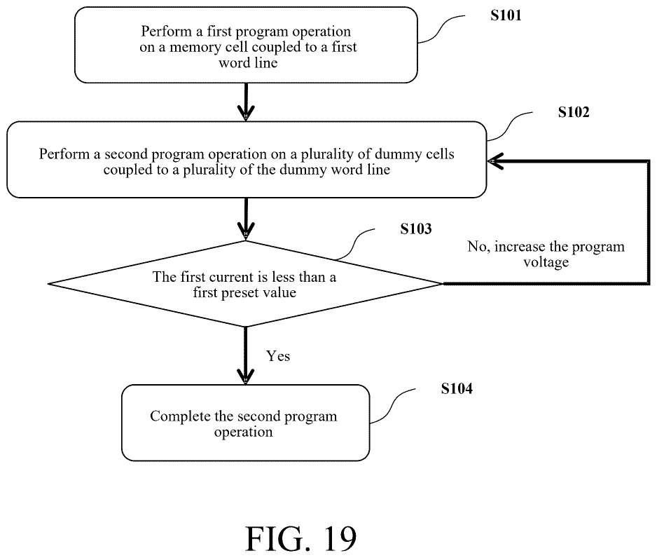

FIG. 19 is a schematic flowchart of programming a dummy cell of a memory string provided by an example of the present disclosure. It should be understood that the operations S101, S102, S103, and S104 shown in FIG. 19 are not exclusive, and other operations may be performed before, after, or between any operations in the operations shown; and sequence of the operations shown in FIG. 19 may be adjusted according to actual needs.

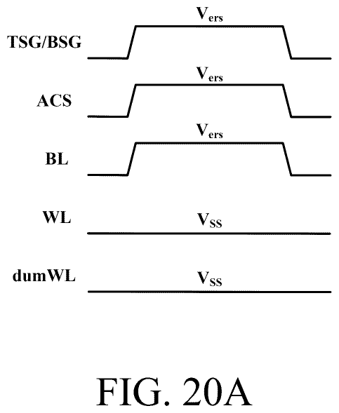

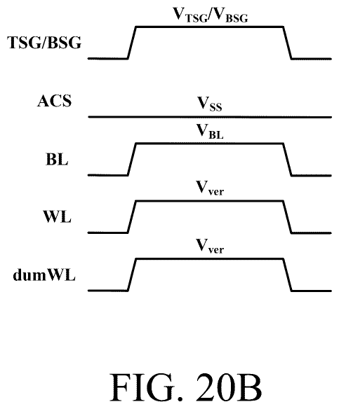

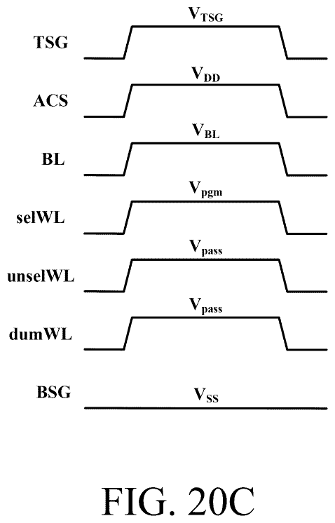

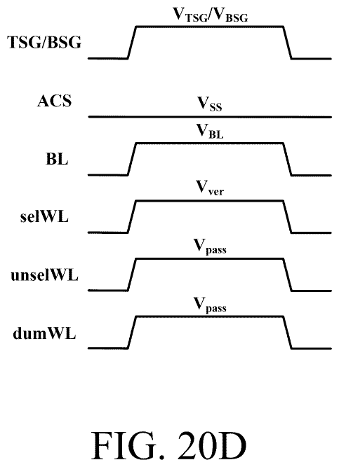

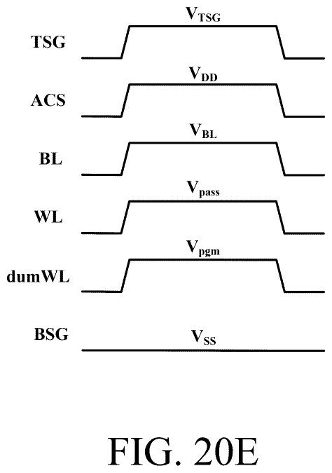

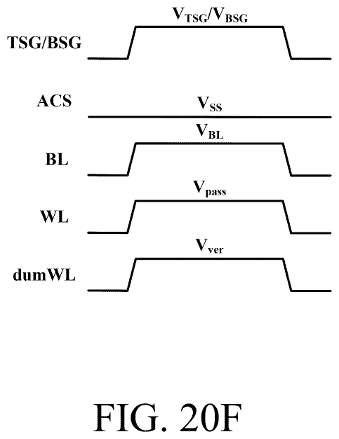

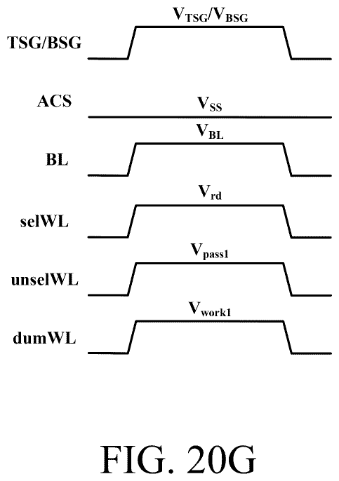

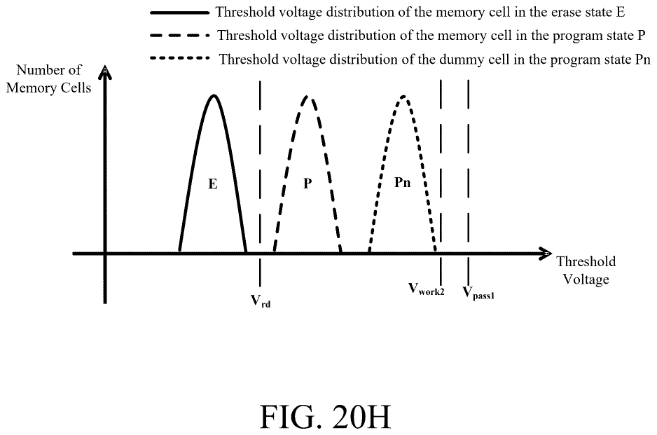

FIG. 20A is a waveform schematic diagram of performing an erasing operation on the memory cell and the dummy cell of the memory string of FIG. 17; and FIG. 20B is a waveform schematic diagram of the erasing operation verification of FIG. 20A. FIG. 20C is a waveform schematic diagram of performing a program operation on a memory cell of the memory string of FIG. 17; and FIG. 20D is a waveform schematic diagram of the program operation verification of FIG. 20C. FIG. 20E is a waveform schematic diagram of performing a program operation on a dummy cell of the memory string of FIG. 17; and FIG. 20F is a waveform schematic diagram of the program operation verification of FIG. 20E. FIG. 20G is a waveform schematic diagram of performing a reading operation on a memory cell of the memory string of FIG. 17.

A specific process of completing the second program operation and an erasing operation and a reading operation associated therewith are described below with reference to FIG. 17, FIG. 18, and FIG. 19, and FIG. 20A to FIG. 20G.

In some examples, the erasing operation is performed before performing operation S101, and the peripheral circuit is configured to: perform an erasing operation on the plurality of memory cells and the plurality of dummy cells.

The erasing operation may be performed by an approach of full word line erase, an approach of odd-even erase, or an approach of other erase. In an approach of full word line erase, the memory cells connected to each word line in the memory block and the dummy cells connected to each dummy word line are simultaneously erased in an erase-verify iteration, a full word line verify is performed after the full word line erase, where the memory cells connected to each word line and the dummy cells connected to each dummy word line are simultaneously subjected to a verify test in an erase-verify iteration.

In an approach of odd-even erase, the memory cells connected to odd word lines and the dummy cells connected to odd dummy word lines are erased separately from the memory cells connected to even word lines and the dummy cells connected to even dummy word lines.

In an approach of odd-even erase, the memory cells connected to odd word lines and the dummy cells connected to odd dummy word lines are separately subjected to verify tests from the memory cells connected to even word lines and the dummy cells connected to even dummy word lines.

In another approach of odd-even erase, the memory cells connected to each word line and the dummy cells connected to each dummy word line are subjected to a verify test simultaneously in an erase-verify iteration.

The erasing operation involves one or more erase-verify iterations, also referred to as erase cycles. In the process of erase cycles, an erase voltage may be applied by an approach of Incremental Step Pulse Erasing (ISPE). As such, the plurality of memory cells and the plurality of dummy cells of the memory string are all in an erase state.

Referring to FIG. 20A, as an example, the erasing operation includes: applying a voltage Vₑᵣₛ to the top select gate line TSG and the bottom select gate line BSG to increase the channel potential of the memory string, applying a voltage V_{SS} (e.g., 0V) to the plurality of word lines WL (e.g., word lines WL0 to WLn), applying a voltage V_{SS} (e.g., 0V) to the plurality of dummy word lines dumWL (e.g., the dummy word line dumWL0 to the dummy word line dumWL2), applying a voltage Vₑᵣₛ (e.g., 20V) to the bit line BL, and applying a voltage Vₑᵣₛ (e.g., 20V) to the source line ACS, to perform an erasing operation on the plurality of memory cells and the plurality of dummy cells.

Referring to FIG. 20B, verification is performed after the erasing, the verification of the erasing operation includes: applying a voltage V_{TSG} and a voltage V_{BSG} to the top select gate line TSG and the bottom select gate line BSG, respectively, to turn on the top select transistor and the bottom select transistor; applying a verify voltage Vᵥₑᵣ (e.g., 1.5V) to the plurality of word lines WL (e.g., word line WL0 to word line WLn) and the plurality of dummy word lines dumWL (e.g., dummy word line dumWL0 to dummy word line dumWL2) to verify memory cells coupled to the plurality of word lines and dummy cells coupled to the plurality of dummy word lines; applying a voltage V_{BL} (e.g., 3V) to the bit line BL; and applying a voltage V_{SS} (e.g., 0V) to the source line ACS. The memory cells coupled to the plurality of word lines and the dummy cells coupled to the plurality of dummy word lines are simultaneously subjected to a verify test in an erase-verify iteration, and an erasing operation on the plurality of memory cells and the plurality of dummy cells is completed by the verify test. As such, the plurality of memory cells and the plurality of dummy cells of the memory string are in an erase state.

In some examples, the program operation involves one or more program-verify iterations, also referred to as program cycles. In the programming process, the program voltage may be applied by an approach of Incremental Step Pulse Programming (ISPP). Verification is performed after programming, where the memory cells coupled to the selected word line are subjected to a verify test simultaneously in program-verify iterations, and a program operation performed on memory cells coupled with the selected word line is completed by the verify test.

In some examples, in operation S101, the peripheral circuit is configured to: perform a first program operation on the plurality of memory cells.

Referring to FIG. 20C, as an example, the programming of the first program operation includes: applying a voltage V_{TSG} and a voltage V_{SS} to the top select gate line TSG and the bottom select gate line BSG respectively; applying a program voltage Vpgm (e.g., 16V) to the selected word line selWL (e.g., word line WLn) to perform programming on the memory cells coupled to the selected word line; applying a pass voltage Vₚₐₛₛ (e.g., 3V) on the non-selected word line unselWL (e.g., word line WL0 to word line WLn−1) to turn on the non-selected memory cells coupled with the non-selected word line; applying a pass voltage Vₚₐₛₛ (e.g., 3V) to the plurality of dummy word lines dumWL (e.g., dummy word line dumWL0 to dummy word line dumWL2) to turn on a plurality of dummy cells coupled with the plurality of dummy word lines; applying a voltage V_{BL} (e.g., 3V) to the bit line BL; and applying a voltage V_{DD} (e.g., 3V) to the source line ACS.

Referring to FIG. 20D, verification is performed after the programming, and the verification of the first program operation includes: applying a voltage V_{TSG} and a voltage V_{BSG} to the top select gate line TSG and the bottom select gate line BSG, respectively, to turn on the top select transistor and the bottom select transistor; applying a verify voltage Vᵥₑᵣ (e.g., 1.5V) to the selected word line selWL (e.g., word line WLn) to verify the memory cell coupled with the selected word line; applying a pass voltage Vₚₐₛₛ (e.g., 3V) on the non-selected word line unselWL (e.g., word line WL0 to word line WLn−1) to turn on the non-selected memory cell coupled with the non-selected word line; applying a pass voltage Vₚₐₛₛ (e.g., 3V) to the plurality of dummy word lines dumWL (e.g., dummy word line dumWL0 to dummy word line dumWL2) to turn on a plurality of dummy cells coupled with the plurality of dummy word lines; applying a voltage V_{BL} (e.g., 3V) to the bit line BL; and applying a voltage V_{SS} (e.g., 0V) to the source line ACS. The memory cells coupled to the selected word line are subjected to a verify test simultaneously in program-verify iterations, and a first program operation on memory cells coupled with the selected word line is completed by the verify test. Similarly, the first program operation is performed on the memory cells coupled to the word line WLn−1 to word line WL0, respectively. As such, the plurality of memory cells of the memory string each store a corresponding weight.

In some examples, in operation S102, the peripheral circuit is configured to: perform a second program operation on the plurality of dummy cells.

Referring to FIG. 20E, as an example, the programming of the second program operation includes: applying a voltage V_{TSG} and a voltage V_{SS} to the top select gate line TSG and the bottom select gate line BSG respectively; applying a program voltage Vpgm (e.g., 16V) to the plurality of dummy word lines dumWL (e.g., the dummy word line dumWL0 to the dummy word line dumWL2) to perform programming on a plurality of dummy cells coupled to the plurality of dummy word lines; applying a pass voltage Vₚₐₛₛ (e.g., 3V) to the plurality of word lines WL (e.g., word lines WL0 to word line WLn) coupled to the plurality of memory cells to turn on the plurality of memory cells; applying a voltage V_{BL} (e.g., 3V) to the bit line BL; and applying a voltage V_{DD} (e.g., 3V) to the source line ACS.

Referring to FIG. 20F, verification is performed after the programming, and the verification of the second program operation includes: applying a voltage V_{TSG} and a voltage V_{BSG} to the top select gate line TSG and the bottom select gate line BSG, respectively, to turn on the top select transistor and the bottom select transistor; applying a verify voltage Vᵥₑᵣ (e.g., 1.5V) to the plurality of dummy word lines dumWL (e.g., dummy word line dumWL0 to dummy word line dumWL2) to verify a plurality of dummy cells coupled to the plurality of dummy word lines; applying a pass voltage Vₚₐₛₛ (e.g., 3V) to the plurality of word lines WL (e.g., word line WL0 to word line WLn) coupled to the plurality of memory cells to turn on the plurality of memory cells; applying a voltage V_{BL} (e.g., 3V) to the bit line BL; and applying a voltage V_{SS} (e.g., 0V) to the source line ACS. The plurality of dummy cells coupled to the plurality of dummy word lines are simultaneously subjected to a verify test in a program-verify iteration, and the second program operation on a plurality of dummy cells coupled with the plurality of dummy word lines is completed by the verify test. As such, a plurality of dummy cells of a memory string are all programmed to a program state.

In some examples, the peripheral circuit is configured to: apply a program voltage, during performing the first program operation, to the first word line by applying a plurality of first step pulse voltages, where a difference between two adjacent ones of first step pulse voltages is a first step length voltage; apply a program voltage, during performing the second program operation, to the third word line by applying a plurality of second step pulse voltages, where a difference between two adjacent second step pulse voltages is a second step length voltage, where a pulse width of the second step pulse voltage is less than a pulse width of the first step pulse voltage, or a second step length voltage is less than the first step length voltage. In an alternative example, the pulse width of the second step pulse voltage is less than the pulse width of the first step pulse voltage, and the second step length voltage is less than the first step length voltage.

Since the memory cell is configured to store the weight, the distribution of the threshold voltage between different memory states (including the erase state and the program state) in which the memory cells are needs to meet a certain read window, as shown in FIG. 9B, there is an interval (also referred to as a read window) between the maximum value of the threshold voltage distribution of the erase state in which the memory cell is and the minimum value of the threshold voltage distribution of the program state in which the memory cell is, and the read voltage V_{rd} for reading the weight of the memory cell is set within the interval.

In contrast to the plurality of memory cells, which are configured to store weights, the plurality of dummy cells are not configured to store weights. The variation of the threshold voltage of the dummy cell may change the equivalent resistance of the plurality of dummy cells in the turned-on state, as long as the threshold voltages of the plurality of dummy cells are within the programmable range (as shown in FIG. 18), and determining whether threshold voltage distributions of different program states of the plurality of dummy cells meet the requirement of a certain read window may not be considered. As such, the compensation accuracy of the plurality of dummy cells can be ensured, so as to adjust their equivalent resistance in a fine-tuned manner that reduces the current variation on the bit line.

In some examples, in operation S103, the peripheral circuit is configured to: apply a first pass voltage to a non-selected word line of the plurality of word lines coupled to the plurality of memory cells, apply a second pass voltage to the plurality of dummy word lines, and obtain a first current passing through the memory string.

For example, a voltage V_{TSG} and a voltage V_{BSG} are applied to the top select gate line TSG and the bottom select gate line BSG, respectively, to turn on the top select transistor and the bottom select transistor, a first pass voltage Vₚₐₛₛ₁ (e.g., 3V) is applied to a plurality of word lines (e.g., word line WL0 to word line WLn) coupled to the plurality of memory cells to turn on the plurality of memory cells, a second pass voltage Vₚₐₛₛ₂ (e.g., 1.5V) is applied to the plurality of dummy word lines (e.g., the dummy word line dumWL0 to the dummy word line dumWL2) to turn on the plurality of dummy cells, a voltage V_{BL} (e.g., 3V) is applied to the bit line BL, a voltage V_{SS} (e. g., 0V) is applied to the source line ACS, to turn on the memory string and sense the current I on the bit line BL.

In an alternative example, a voltage V_{TSG} and a voltage V_{BSG} are applied to the top select gate line TSG and the bottom select gate line BSG, respectively, to turn on the top select transistor and the bottom select transistor, a read voltage V_{rd} (e.g., 1.5V) is applied to the selected word line (e.g., word line WLn) to perform reading on a memory cell coupled to the selected word line, a first pass voltage Vₚₐₛₛ₁ (e.g., 3V) is applied to the non-selected word line (e.g., word line WL0 to word line WLn−1) to turn on the non-selected memory cell coupled with the non-selected word line, a second pass voltage Vₚₐₛₛ₂ (e.g., 1.5V) is applied to the plurality of dummy word lines (e.g., dummy word line dumWL0 to dummy word line dumWL2) to turn on the plurality of dummy cells, a voltage V_{BL} (e.g., 3V) is applied to the bit line BL, and a voltage V_{SS} (e. g., 0V) is applied to the source line ACS, to turn on the memory string and sense the current I on the bit line BL. With reference to FIG. 18, the higher the program state in which the plurality of dummy cells are (e.g., the nth program state Pn is higher than the first program state P1), the larger the equivalent resistance of the plurality of dummy cells, and thus the smaller the first current passing through the memory string is when the memory string is in a turned-on state. As such, the magnitude of the first current passing through the memory string is adjusted according to different program states of the plurality of dummy cells of the memory string.

Referring to FIG. 19, in some examples, the second program operation involves one or more program-verify iterations, and in the second program operation, a program voltage may be applied by an approach of Incremental Step Pulse Programming. Whether to increase the program voltage is determined according to whether the first current obtained is less than a first preset value. In some examples, the first preset value may be an empirical value, or may be a default value configured when the semiconductor structure (or the semiconductor device) leaves the factory and obtained through a large number of simulation experiments. For example, the first preset value may be in a range of 30 nA to 50 nA. For example, the first preset value may be 32 nA, 34 nA, 35 nA, 36 nA, 37 nA, 38 nA, 39 nA, 40 nA, 41 nA, 42 nA, 43 nA, 44 nA, 55 nA, 46 nA, or 48 nA. For example, when the first current is less than the first preset value, the next program operation is not performed; when the first current is greater than or equal to the first preset value, the next program voltage is obtained by increasing a step length voltage (as the second step length voltage described below) in comparison with the previous program voltage to perform the next program operation.

Referring to FIG. 19, in some examples, the peripheral circuit is configured to perform operation S103 to operation S104: completing the second program operation when the first current is less than the first preset value.

Referring to FIG. 19, in some examples, the peripheral circuit is configured to perform operations S103, S102, S103 to S104: increasing a program voltage of the second program operation according to the first current being greater than or equal to a first preset value and continuing to perform a second program operation; continuing to apply a first pass voltage to the second word line and applying a second pass voltage to the third word line to obtain a corresponding first current; and completing the second program operation when the first current is less than the first preset value.

As such, when the first current is less than the first preset value, the current variation on the bit line can be reduced by reducing the first current when the first operation is performed; in this way, the current consistency on the bit line in the process of performing the first operation may be improved, and the error rate in the process of performing the first operation may be reduced or eliminated.

In some examples, after performing operation S104, the peripheral circuit is configured to: perform a reading operation on the memory cell coupled to the first word line.

Referring to FIG. 20G, as an example, the reading operation includes: applying a voltage V_{TSG} and a voltage V_{BSG} to the top select gate line TSG and the bottom select gate line BSG, respectively, to turn on the top select transistor and the bottom select transistor, applying a read voltage V_{rd} (e.g., 1.5V) to the selected word line selWL (e.g., word line WLn) to perform reading on a memory cell coupled to the selected word line, applying a first pass voltage Vₚₐₛₛ₁ (e.g., 3V) to the non-selected word line unselWL (e.g., word line WL0 to word line WLn−1) to turn on the non-selected memory cell coupled with the non-selected word line, applying a first operating voltage V_{word1} (e.g., 2.5V) less than the second pass voltage Vₚₐₛₛ₂ (e.g., 3V) to the plurality of dummy word line dumWL (e.g., dummy word line dumWL0 to dummy word line dumWL2) such that a plurality of dummy cells coupled with the plurality of dummy word lines are turned on, applying a voltage V_{BL} (e.g., 3V) to the bit line BL, applying a voltage V_{SS} (e.g., 0V) to the source line ACS, to turn on the memory string and sense the current I on the bit line BL. As such, weights stored in the plurality of memory cells of the memory string are read.

Referring to FIG. 18, in some examples, the peripheral circuit is further configured to: apply a read voltage to the first word line, apply a first pass voltage to the second word line, and apply a first operating voltage less than the second pass voltage to the plurality of third word lines during performing a reading operation on the memory cell coupled with the first word line, such that the plurality of dummy cells operate in a linear region. Here, the first operating voltage is greater than the maximum threshold voltage of the threshold voltage distribution of the program state of the plurality of dummy cells, and may be less than a saturation region initial voltage of the dummy cell; and the second pass voltage is greater than or equal to the saturation region initial voltage. For example, referring to FIG. 18, a plurality of dummy cells are in the nth program state Pn, the first operating voltage V_{work1} is greater than the maximum threshold voltage of the threshold voltage distribution of the nth program state Pn and less than the saturation region initial voltage Vₛₐₜₙ of the nth program state Pn. As an example, a plurality of dummy cells are in the first program state P1, the first operating voltage is greater than the maximum threshold voltage of the threshold voltage distribution of the first program state P1 and less than the saturation region initial voltage Vₛₐₜ₁ of the first program state P1.

It should be noted that the operating state (turned-on state) of the dummy cell may be divided into a linear region operating state and a saturation region operating state, and the saturation region initial voltage is the threshold voltage for distinguishing the operating state of the linear region and the operating state of the saturation region. In the operating state of the dummy cell, when the operating voltage received by the dummy word line coupled to the dummy cell is less than the saturation region initial voltage, the dummy cell operates in the linear region; and when the operating voltage received by the dummy word line coupled to the dummy cell is greater than or equal to the saturation region initial voltage, the dummy cell operates in the saturation region. The equivalent resistance of the dummy cell operating in the linear region is relatively small and does not vary with the voltage variation of the source and the drain of the dummy cell; and the equivalent resistance of the dummy cell operating in the saturation region is relatively large and varies with the voltage variation of the source and the drain of the dummy cell.

As such, compared with the plurality of dummy cells operating in the saturation region, the plurality of dummy cells operating in the linear region cause the equivalent resistance of the plurality of dummy cells in the operating state to be relatively small and do not significantly vary with the voltage variation on the source and the drain of the dummy cell. Therefore, the stability of the plurality of dummy cells in the operating state is ensured, the current variation on the bit line caused by the plurality of dummy cells can be avoided or reduced in the reading operation, and the current variation on the bit line can be reduced, so as to improve the current consistency on the bit line in the process of performing the first operation, and reduce or eliminate the error rate in the process of performing the first operation.

FIG. 20H is a schematic diagram of comparison between a threshold voltage distribution of a memory cell in an erase state/program state and a threshold voltage distribution of a dummy cell in a program state provided by an example of the present disclosure.

Referring to FIG. 20H, in some examples, the peripheral circuit is further configured to: perform a first program operation, where the memory cell coupled to the first word line has a first threshold voltage; perform a second program operation, where one of the plurality of dummy cells has a second threshold voltage that is greater than the first threshold voltage; apply a read voltage to the first word line; apply a first pass voltage to the second word line; and apply a second operating voltage to the plurality of third word lines during performing a reading operation on the memory cell coupled to the first word line, where the second operating voltage is less than the first pass voltage. Here, the first threshold voltage is within the threshold voltage distribution of the program state of the memory cell, the second threshold voltage is within the threshold voltage distribution of the program state of the dummy cell, the maximum threshold voltage of the threshold voltage distribution of the program state of the memory cell is less than the minimum threshold voltage of the threshold voltage distribution of the program state of the dummy cell, and the second operating voltage V_{work2} and the first pass voltage Vₚₐₛₛ₁ are both greater than the maximum threshold voltage of the threshold voltage distribution of the program state of the dummy cell.

Referring to FIG. 20H, the memory cell is in the program state P or the erase state E, and the minimum threshold voltage of the threshold voltage distribution of the program state P of the memory cell is greater than the maximum threshold voltage of the threshold voltage distribution of the erase state E of the memory cell; and the dummy cell is in the program state Pn, and the minimum threshold voltage of the threshold voltage distribution of the program state Pn of the dummy cell is greater than the maximum threshold voltage of the threshold voltage distribution of the program state P of the memory cell.

As such, compared with the memory cell, the dummy cell is programmed to a higher threshold voltage (e.g., the program state Pn of the dummy cell), and a lower pass voltage (e.g., a second operating voltage V_{work2} less than the first pass voltage Vₚₐₛₛ₁) is applied to the dummy word line coupled to the dummy cell in the reading operation, so as to ensure that a large equivalent resistance of the dummy cell in the operating state. By adding the large equivalent resistance of the dummy cell, the impact of the equivalent resistance corresponding to the memory cell coupled to the non-selected word line on the current on the bit line can be reduced, and the current on the bit line can be reduced while ensuring that the first operation can be performed.

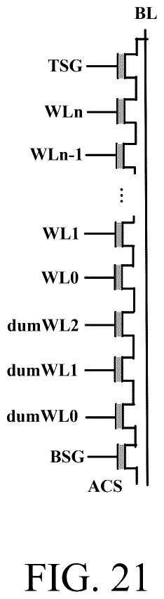

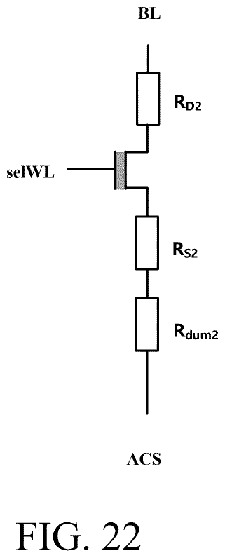

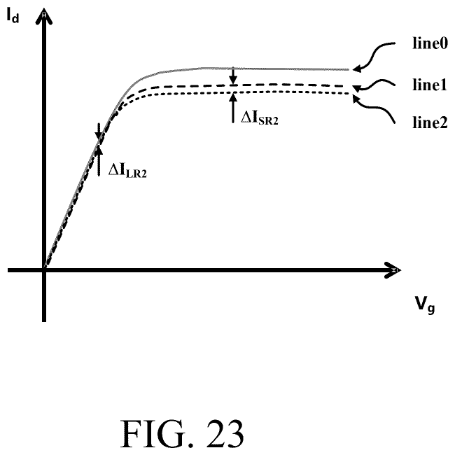

FIG. 21 is a fourth schematic diagram of a memory string with a first end connected to a source line and a second end connected to a bit line provided by an example of the present disclosure. FIG. 22 is a schematic diagram of a current-voltage characteristic curve of the dummy word lines of the memory string of FIG. 21 in different program states. FIG. 23 is a flowchart of programming dummy cell of the memory string of FIG. 21. It should be noted that the memory string shown in FIG. 21 may be regarded as similar to the memory string shown in FIG. 17. Compared with the reading operation performed on the memory string shown in FIG. 17, the pass voltage applied to the non-selected word line is different for the reading operation performed on the memory string shown in FIG. 21.

Referring to FIG. 22, when the memory string is in the turned-on state, the equivalent resistance corresponding to the memory cell between the selected memory cell (the memory cell coupled to the selected word line selWL) and the source line ACS is the first equivalent resistance R_{S2}, the equivalent resistance corresponding to the dummy cell between the selected memory cell and the source line ACS is the third equivalent resistance R_{dum2}, and the equivalent resistance corresponding to the memory cell between the selected memory cell and the bit line BL is the second equivalent resistance R_{D2}.

FIG. 23 shows the current-voltage characteristic curve of the current I_{d} on the bit line BL and the gate voltage V_{g} received from the selected word line selWL when the memory string is in the turned-on state. The curve line0 may be regarded as a current-voltage characteristic curve measured when the memory cells of the memory string are all in an erase state. The curve line1 may be regarded as a current-voltage characteristic curve measured when at least part of the memory cells of the memory string are in a program state, where the selected word line selWL is a word line close to the source line ACS, such as word line WL2. The curve line2 may be regarded as a current-voltage characteristic curve measured when at least part of the memory cells of the memory string are in a program state, where the selected word line selWL is a word line close to the bit line BL, such as the word line WLn−2.

With reference to FIG. 21, FIG. 22, and FIG. 23, compared with the current difference ΔI_{LR0} in the linear region shown in FIG. 13, the current difference ΔI_{LR2} in the linear region between the curve line1 and the curve line2 shown in FIG. 23 is smaller, e.g., the current difference ΔI_{LR2} is less than the current difference ΔI_{LR0}; compared with the current difference ΔI_{SR0} in the linear region shown in FIG. 13, the current difference ΔI_{SR2} in the saturation region between the curve line1 and the curve line2 shown in FIG. 23 is smaller, e.g., the current difference ΔI_{SR2} is less than the current difference ΔI_{SR0}.

Referring to FIG. 21, FIG. 22, and FIG. 23, in some examples, the peripheral circuit is further configured to: apply a read voltage to the first word line, apply a third pass voltage to the second word line, and apply a third operating voltage to the plurality of third word lines during performing a first reading operation on the memory cell coupled with the first word line, according to the memory cell coupled with the first word line being at a first position in the memory string; apply a read voltage to the first word line, apply a fourth pass voltage to the second word line, and apply a third operating voltage to the plurality of third word lines during performing a second reading operation on the memory cell coupled with the first word line, according to the memory cell coupled with the first word line being at a second position in the memory string, where the first position is closer to the bit line than the second position, and the third pass voltage is greater than the fourth pass voltage.

In some examples, the third pass voltage and the fourth pass voltage are both greater than or equal to the first pass voltage. In an alternative example, the third pass voltage is greater than the fourth pass voltage, and the fourth pass voltage is greater than the first pass voltage. In some examples, the specific value of the third pass voltage and the fourth pass voltage may be an empirical value, or may be a default value configured when the semiconductor structure (or the semiconductor device) leaves the factory and obtained through a large number of simulation experiments. For example, the specific value of the third pass voltage and the fourth pass voltage depends on the actual measurement result, the driving capability of the row decoder/word line driver, and the like.

With reference to FIG. 21, FIG. 22 and FIG. 23, compared with the current shown in the curve line1 in FIG. 16, the current shown in the curve line1 in FIG. 23 is larger; compared with the current shown in the curve line2 in FIG. 16, the current shown in the curve line2 in FIG. 23 is larger. As an example, when in the first position, the peripheral circuit is configured to perform a first reading operation on the memory cell coupled with the selected word line, and the first reading operation includes: applying a read voltage V_{rd} (e.g., 1.5V) to the selected word line selWL (e.g., word line WLn) to perform reading on the memory cell coupled to the selected word line, applying a third pass voltage (e.g., 3.2V) greater than the first pass voltage Vₚₐₛₛ₁ (e.g., 3V) to the non-selected word line unselWL (e.g., word line WL0 to word line WLn−1) to turn on the non-selected memory cell coupled with the non-selected word line; when in the second position, the peripheral circuit is configured to perform a second reading operation on the memory cell coupled with the selected word line, the second reading operation includes: applying a read voltage V_{rd} (e.g., 1.5V) to the selected word line selWL (e.g., word line WLn) to perform reading on the memory cell coupled to the selected word line, applying a fourth pass voltage (e.g., 3V) greater than or equal to the first pass voltage Vₚₐₛₛ₁ (e.g., 3V) and less than the third pass voltage (e.g., 3.2V) to the non-selected word line unselWL (e.g., word line WL0 to word line WLn−1), to turn on the non-selected memory cell coupled with the non-selected word line.

As such, compared with the second reading operation, the pass voltage applied to the non-selected word line (for example, word line WL0 to word line WLn−1) in the first reading operation is larger and can increase the current on the bit line, which is equivalent to reducing the difference from the current on the bit line in the second reading operation, reducing the impact of the equivalent resistance corresponding to the memory cell coupled with the non-selected word line on the current on the bit line, and the current on the bit line can be reduced while ensuring that the first operation can be performed.

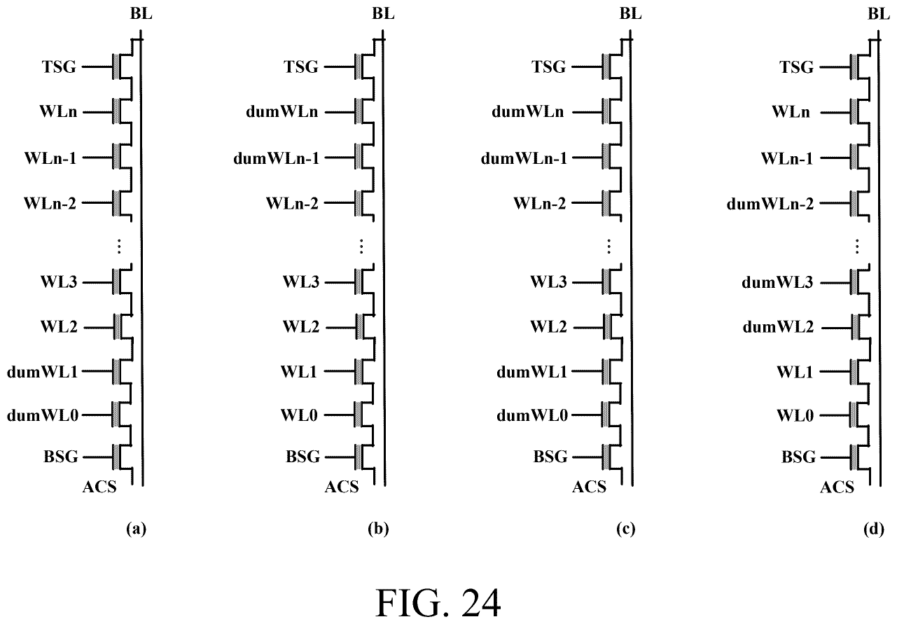

FIG. 24 is a schematic diagram of some memory strings with a first end connected to a source line and a second end connected to a bit line provided by an example of the present disclosure. FIG. 24 (a), FIG. 24 (b), FIG. 24 (c), and FIG. 24 (d) are examples of different memory strings, respectively. Although the number of dummy cells shown in FIG. 24 (a), FIG. 24 (b), FIG. 24 (c), and FIG. 24 (d) is 2, 2, 4 and 3, respectively, the number of dummy cells is not limited to those numbers shown in FIG. 24, and the number of dummy cells may be a number greater than 4 (e.g., 5 or 6).

In some examples, the position in the memory string of each dummy cell in the plurality of dummy cells may be set, such that the dummy cell may be close to the bit line BL or the source line ACS and may also be away from the bit line BL or the source line ACS. Taking the (n+1) word lines shown in FIG. 11 as a reference, since the word line WL0 to the word line WLn are sequentially numbered in a direction from the source line ACS to the bit line BL, their positions relative to the bit line BL or the source line ACS has been illustrated. A word line with a target number (a natural number greater than 1) among the (n+1) word lines shown in FIG. 11 may be replaced with a dummy word line, and a memory cell coupled to the dummy word line may be replaced with a dummy cell, to obtain the memory string of FIG. 24 or a memory string similar to FIG. 24.

Referring to FIG. 24, in some examples, as shown in FIG. 24 (a), the plurality of dummy cells includes a bottom dummy cell between the source line and the plurality of memory cells, or as shown in FIG. 24 (b), a top dummy cell between the bit line and the plurality of memory cells. In an alternative example, as shown in FIG. 24 (c), the plurality of dummy cells includes a bottom dummy cell between the source line and the plurality of memory cells and a top dummy cell between the bit line and the plurality of memory cells. In some other examples, as shown in FIG. 24 (d), the plurality of dummy cells includes middle dummy cells located away from the source line and away from the bit line.

In some examples, compared with the top dummy cell, the bottom dummy cell has a larger impact on the current variation on the bit line, and a more significant compensation effect. In the reading operation, the current variation on the bit line caused by the plurality of dummy cells can be avoided or reduced, and the current variation on the bit line can be reduced, thereby improving the current consistency on the bit line in the process of performing the first operation, and reducing or eliminating the error rate in the process of performing the first operation.

In some examples, a plurality of memory strings located in the same column have a first end connected to a source line and a second end connected to a bit line; the first word line is coupled to corresponding memory cells in a plurality of memory strings located in the same column; the peripheral circuit is further configured to: perform a reading operation on corresponding memory cells coupled to the first word line, obtain a second current passing through the bit line, and obtain a result of the first operation based on the second current.

A specific process of performing the first operation may be understood with reference to the related description of FIG. 10, where a word line having a target number (a natural number greater than 1) in the word line WL0 to the word line WLend shown in FIG. 10 is replaced with dummy word lines, and memory cells coupled to the dummy word lines are replaced with dummy cells. For a plurality of dummy word lines and a plurality of dummy cells coupled to the plurality of dummy word lines, reference may be made to the foregoing examples, and details are not provided again.

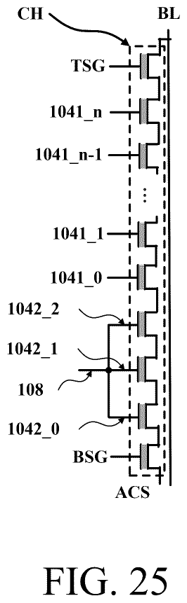

In some examples, the third word line includes a first portion (referring to the connection structure 108 in FIG. 25) and a plurality of second portions connected to the first portion (referring to the second gate layer dumGL0, the second gate layer dumGL1, and the second gate layer dumGL2 in FIG. 25); a first end of each second portion is connected to a gate terminal of a corresponding dummy cell; and a second end of each second portion is commonly connected to the first portion, where the first portion is configured to receive the second pass voltage.

The first ends of the plurality of second portions of the third word line are coupled to the plurality of dummy cells, respectively, the second ends of the plurality of second portions commonly contact and are electrically connected to the first portion of the third word line to merge the gate terminals of the plurality of dummy cells together, the row decoder/word line driver may transfer the respective voltages (e.g., the program voltages applied to the gate terminals of the plurality of dummy cells in the second program operation, the second pass voltages applied to the gate terminals of the plurality of dummy cells in the operation of obtaining the first current, or the first operating voltage or the second operating voltage applied to the gate terminals of the plurality of dummy cells in the reading operation) to the gate terminals of the plurality of dummy cells through the first portion of the third word line, which may reduce the number of row decoder/word line drivers and the cost.

Since the drift of the threshold voltage of the dummy cell is relatively sensitive (e.g., compared with the dummy cell operating in the saturation region, the drift of the threshold voltage of the dummy cell is very sensitive when the dummy cell operates in the linear region), the gate terminals of the plurality of dummy cells are merged together to avoid or reduce the lateral charge loss of the dummy cell, which improves the cell retention characteristics of the dummy cell.

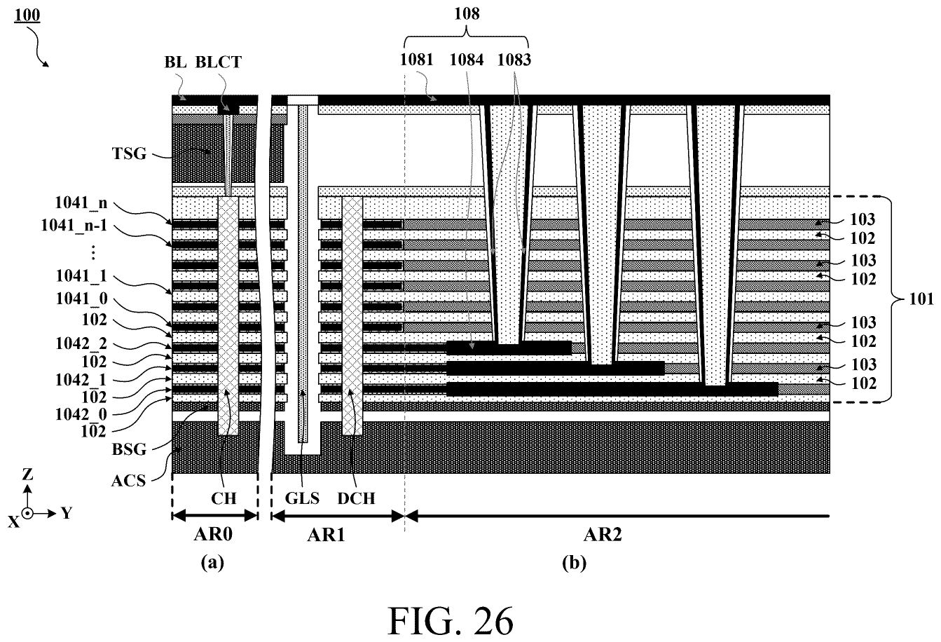

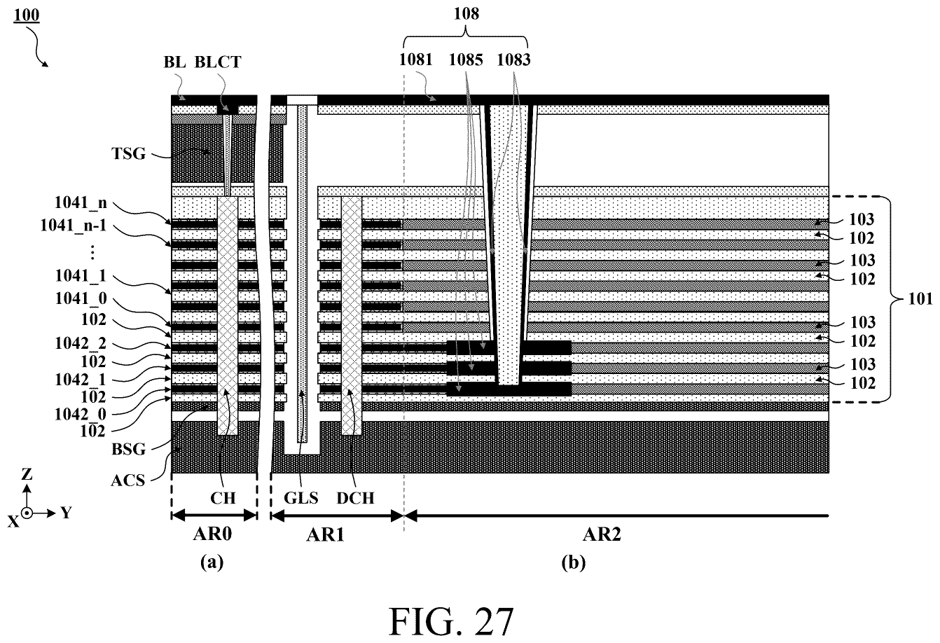

FIG. 25 is a schematic diagram of memory strings commonly connected to a connection structure of a plurality of second gate layers coupled with a plurality of dummy cells provided by an example of the present disclosure. FIG. 26 is a first cross-sectional schematic diagram of a semiconductor structure including a connection structure provided by an example of the present disclosure. FIG. 27 is a second cross-sectional schematic diagram of a semiconductor structure including a connection structure provided by an example of the present disclosure. It should be noted that FIG. 26 (a) and FIG. 26 (b) are schematic diagrams of different cross-sections of a semiconductor structure, and FIG. 27 (a) and FIG. 27 (b) are schematic diagrams of different cross-sections of a semiconductor structure. FIG. 26 (a) and FIG. 27 (a) show, for example, that the first end of the memory string is connected to the source line through the top select transistor, the second end is connected to the bit line through the bottom select transistor, the channel structure of the memory string is shown briefly, and specifics of the channel structure of the memory string may be understood with reference to the related description of FIG. 5.

With reference to FIG. 25 and FIG. 26, or with reference to FIG. 25 and FIG. 27, in a second aspect, an example of the present disclosure provides another semiconductor structure; and the another semiconductor structure includes a memory array configured to perform a first operation and a peripheral circuit coupled to the memory array; the memory array includes a memory string; a first end of the memory string is connected to a source line, and a second end of the memory string is connected to a bit line; the memory string includes a plurality of memory cells and a plurality of dummy cells, where the plurality of memory cells are coupled to a plurality of first gate layers; the plurality of dummy cells are coupled to a plurality of second gate layers; first ends of the plurality of second gate layers are coupled to the plurality of dummy cells, respectively, and second ends of the plurality of second gate layers commonly contact and are electrically connected to the connection structure; and the connection structure includes a conductive material.

As an example, the first end of the memory string is connected to the source line ACS through the bottom select transistor, the second end is connected to the bit line BL through the top select transistor, the gate terminal of the top select transistor is connected to the top select gate line TSG, and the gate terminal of the bottom select transistor is connected to the bottom select gate line BSG. The memory string includes a plurality of memory cells and a plurality of dummy cells; the plurality of memory cells are coupled to the first gate layer 1041_0, the first gate layer 1041_1, . . . , the first gate layer 1041_n1 and the first gate layer 1041_n; the plurality of dummy cells are coupled to first ends of the second gate layer 1042_0, the second gate layer 1042_1 and the second gate layer 1042_2; and second ends of the second gate layer 1042_0, the second gate layer 1042_1 and the second gate layer 1042_2 commonly contact and are electrically connected to the connection structure 108.

In some examples, the conductive material includes, but is not limited to, tungsten (W), cobalt (Co), copper (Cu), aluminum (Al), polysilicon, doped silicon, silicide, or any combination thereof. In some examples, the material of the connection structure is the same as or similar to the material of the second gate layer. In some examples, the material of the connection structure includes a metal layer, such as a tungsten layer.

Although the number of dummy cells shown in FIG. 25 is 3, the number of dummy cells is not limited to the number shown in FIG. 25, and the number of dummy cells may be 2 or greater than 3 (e.g., 4, 5, or 6). Although the plurality of dummy cells shown in FIG. 25 are arranged adjacent to each other, the plurality of dummy cells may also be spaced apart with each other (not shown in FIG. 25), and the plurality of dummy cells may be partially spaced apart with each other and partially arranged adjacent to each other (not shown in FIG. 25). Although the dummy cell shown in FIG. 25 is located at the bottom of the memory string between the source line and the plurality of memory cells, the position of the dummy cell is not limited to the position shown in FIG. 25, and the dummy cell may also be located at the top of the memory string between the bit line and the plurality of memory cells (not shown in FIG. 25). In other examples, the dummy cell may also be located in the middle of the memory string away from the source line and away from the bit line (not shown in FIG. 25).

It should be noted that the memory string shown in FIG. 25 may also be understood with reference to the related description of FIG. 14 to FIG. 24. In FIG. 14 to FIG. 24, the second ends of the dummy word lines of the memory string needs to be understood as being commonly connected to the connection structure, and the first ends of the dummy word lines of the memory string shown in FIG. 14 to FIG. 24 are connected to the gate terminal of the corresponding dummy cell. The plurality of second gate layers and the plurality of dummy cells coupled to the plurality of second gate layers as shown in FIG. 25 may be understood with reference to the plurality of dummy word lines and the plurality of dummy cells coupled to the plurality of dummy word lines in the foregoing examples, and details are not described herein again.

The first ends of the plurality of second gate layers are coupled to the plurality of dummy cells, respectively the second ends of the plurality of second gate layers commonly contact and are electrically connected to the connection structure to merge the plurality of second gate layers together, and the row decoder/word line driver may transfer the corresponding voltage (for example, the program voltage applied to the second gate layer in the second program operation, the second pass voltage applied to the second gate layer in the operation of obtaining the first current, or the first operating voltage or the second operating voltage applied to the second gate layer in the reading operation) to the plurality of second gate layers through the connection structure, thereby reducing the number of row decoder/word line drivers and saving the cost.

Since the drift of the threshold voltage of the dummy cell is relatively sensitive (e.g., compared with the dummy cell operating in the saturation region, the drift of the threshold voltage of the dummy cell is very sensitive when the dummy cell operates in the linear region), the plurality of second gate layers are merged together to avoid or reduce the lateral charge loss of the dummy cell, which improves the cell retention characteristics of the dummy cell.

In some examples, the plurality of dummy cells include: a bottom dummy cell between the source line and the plurality of memory cells, or a top dummy cell between the bit line and the plurality of memory cells. In some examples, compared with the top dummy cell, the bottom dummy cell has a larger impact on the current variation on the bit line and a more significant compensation effect.

In some examples, a plurality of memory strings located in the same column have a first end connected to a source line and a second end connected to a bit line, and the first gate layers are coupled to corresponding memory cells in the plurality of memory strings located in the same column.

Here, referring to that the second ends of the dummy word lines of the memory strings shown in FIG. 14 to FIG. 24 are commonly connected to the connection structure, the examples of the plurality of dummy word lines and the plurality of dummy cells coupled to the plurality of dummy word lines may be understood with reference to the examples shown in FIG. 14 to FIG. 24, and details are not described herein again.

Although the number of dummy cells shown in FIG. 25 is 3, the number of dummy cells is not limited to the number shown in FIG. 25, and the number of dummy cells may be 2 or greater than 3 (e.g., 4, 5, or 6).

Although the plurality of dummy cells shown in FIG. 25 are arranged adjacent to each other, the plurality of dummy cells may also be spaced apart with each other (not shown in FIG. 25), and the plurality of dummy cells may be partially spaced apart with each other and partially arranged adjacent to each other (not shown in FIG. 25).

Although the dummy cell shown in FIG. 25 is located at the bottom of the memory string between the source line and the plurality of memory cells, the position of the dummy cell is not limited to the position shown in FIG. 25, and the dummy cell may also be located at the top of the memory string between the bit line and the plurality of memory cells (not shown in FIG. 25). In other examples, the dummy cell may also be located in the middle of the memory string away from the source line and away from the bit line (not shown in FIG. 25).

In a third aspect, an example of the present disclosure provides another semiconductor structure, referring to FIG. 26 and FIG. 27, the semiconductor structure 100 includes: a stack structure 101 including a gate layer and an insulating layer 102 spaced apart with each other; the stack structure 101 includes a plurality of gate layers; the plurality of gate layers includes a plurality of first gate layers (for example, a first gate layer 1041_0 to 1041_n) and a plurality of second gate layers (for example, second gate layers 1042_0 to 1042_2); a memory structure (not shown in FIG. 26 and FIG. 27) extending through the stack structure and including a plurality of memory cells and a plurality of dummy cells, where the memory cell is coupled to the first gate layer, the dummy cell is coupled to the second gate layer, and a connection structure 108 includes a conductive material and is in contact with and electrically connected to the plurality of second gate layers. As such, the first ends of the plurality of second gate layers are coupled to the dummy cells, respectively, the second ends of the plurality of second gate layers commonly contact and are electrically connected to the connection structure to merge the plurality of second gate layers together, the row decoder/word line driver may be coupled to the plurality of second gate layers through a connection structure, which may reduce the number of row decoder/word line drivers and the cost.

Herein, the stack structure 101 and the memory structure of the memory string may be understood with reference to the related description of FIG. 5, and details are not described herein again.

Here, a first region AR0 may be regarded as a memory array, and a second region AR1 may be regarded as a region where the interface region between the memory array and the lead-out region is located; a third region AR2 may be regarded as a lead-out region of the gate layer; the first region interfaces with the interface region in the row direction, and the lead-out region interfaces with the interface region in the row direction.

In some examples, FIG. 26 (b) and FIG. 27 (b) may be cross-sectional schematic diagrams perpendicular to the extension direction of the gate line slit GLS, and the gate line slit GLS extends along the X-Z plane.

In some examples, the memory string CH is located in the first region AR0, the first end of the memory string CH is connected to the source line ACS through the bottom select transistor, the second end is connected to the bit line BL through the top select transistor and the bit line contact BLCT, the gate terminal of the top select transistor is connected to the top select gate line TSG, and the gate terminal of the bottom select transistor is connected to the bottom select gate line BSG. The memory string includes a plurality of memory cells and a plurality of dummy cells, the plurality of memory cells are coupled to the first gate layer 1041_0, the first gate layer 1041_1, . . . , the first gate layer 1041_n1 and the first gate layer 1041_n; the plurality of dummy cells are coupled to the first ends of the second gate layer 1042_0, the second gate layer 1042_1, and the second gate layer 1042_2; and the second ends of the second gate layer 1042_0, the second gate layer 1042_1, and the second gate layer 1042_2 commonly contact and are electrically connected to the connection structure 108. In some examples, the dummy memory string DCH is located in the second region AR1, and the dummy memory string DCH is not configured to store data. Although the dummy memory string DCH may be coupled to the corresponding first gate layer and second gate layer, the first end of the dummy memory string DCH need not be connected to the source line ACS, or the second end need not be connected to the bit line BL.

In some examples, the stack structure 101 in the third region AR2 further includes a dielectric layer 103 and an insulating layer 102 spaced apart with each other. For example, the material of dielectric layer 103 includes silicon nitride, and the material of insulating layer 102 includes silicon oxide.

In some examples, the material of the top select gate line TSG and the bottom select gate line BSG includes polysilicon. In some examples, the material of the bit line BL, the bit line contact BLCT includes a metal layer, such as a tungsten layer.

Referring to FIG. 26 and FIG. 27, in some examples, the semiconductor structure includes a memory cell array located in the first region AR0 and a connection structure (connection structure corresponding to the plurality of first gate layers is not shown in FIG. 26 and FIG. 27) located in the third region AR2, and the connection structure is configured to lead out the gate layer of the memory cell array. It should be noted that to illustrate the common lead-out of the plurality of second gate layers to a connection structure, the electrical connection between a connection structure and the plurality of second gate layers is shown in FIG. 26 and FIG. 27, and the case in which each of the plurality of first gate layers is lead out separately is not shown. The case in which each first gate layer is lead out separately may be understood with reference to the case in which each second gate layer is lead out in FIG. 26. For example, the first gate layer 1041_0 may extend and electrically connect to a first extension component (referring to the first extension component 1084 shown in FIG. 26) that extends and is electrically connected to a first contact structure (referring to the first contact structure 1082 shown in FIG. 26), the first contact structure extends and is electrically connected to a first connection line (referring to the first connection line 1081 shown in FIG. 26) that is located over the stack structure 101.

In some examples, the plurality of first gate layers are coupled to the plurality of memory cells and extend along a row direction of the memory cell array, the plurality of second gate layers are coupled to the plurality of dummy cells and extend along a row direction of the memory array, the first gate layer and the second gate layer may extend within the first region AR0, extend from the first region AR0 through the second region AR1 and extend to the third region AR2, and are lead out by the corresponding connection structure in the third region AR2. For example, the plurality of second gate layers are coupled to the plurality of dummy cells and extend along a row direction of the memory cell array, extend from the first region AR0 through the second region AR1 and extend to the third region AR2, and are lead out by the corresponding connection structure 108 in the third region AR2.

Referring to FIG. 26, in some examples, the connection structure 108 includes: a first connection line 1081 located over the stack structure 101; a plurality of first contact structures 1082 with first ends extending and connected to the second gate layers, respectively, and second ends commonly connected to the first connection line 1081. As an example, a first end of a first contact structure 1082 extends and is connected to a corresponding second gate layer, and second ends of the plurality of first contact structures 1082 are commonly connected to the first connection line 1081 to merge a plurality of second gate layers (for example, the second gate layers 1042_0 to 1042_2) together. As an example, the connection structure 108 further includes a first extension component 1084 corresponding to the plurality of first contact structures 1082, a first contact structure 1082 extending vertically may be connected to a corresponding second gate layer through a horizontally extending first extension component 1084, and second ends of the plurality of first contact structures 1082 are commonly connected to the first connection line 1081 to merge the plurality of second gate layers together.

Referring to FIG. 27, in some examples, the connection structure 108 includes: a first connection line 1081 located over the stack structure 101; a second contact structure 1083 with a first end extending through at least some of the plurality of second gate layers and connected to the plurality of second gate layers (e.g., the second gate layers 1042_0 to 1042_2) and a second end connected to the first connection line 1081. As an example, the connection structure 108 further includes a second extension component 1085 corresponding to the plurality of second gate layers, first ends of the second contact structure 1083 may be connected to corresponding ones of the plurality of second gate layers, respectively, through the plurality of second extension components 1085, and a second end of the second contact structure 1083 is connected to the first connection line 1081 to merge the plurality of second gate layers together.

In some examples, the plurality of second gate layers includes: a bottom dummy gate layer (not shown in FIG. 26 and FIG. 27) at the bottom of the stack structure, or a top dummy gate layer (not shown in FIG. 26 and FIG. 27) at the top of the stack structure.

Examples of the present disclosure may understand as some example implementations that show how the second ends of the plurality of second gate layers of the semiconductor structure are in contact and electrically connected to the connection structure provided in the second aspect. The semiconductor structure provided by an example of the present disclosure is similar to the semiconductor structure provided in the second aspect. For technical features not disclosed in the examples of the present disclosure, reference may be made to the foregoing examples for understanding, and details are not provided again.

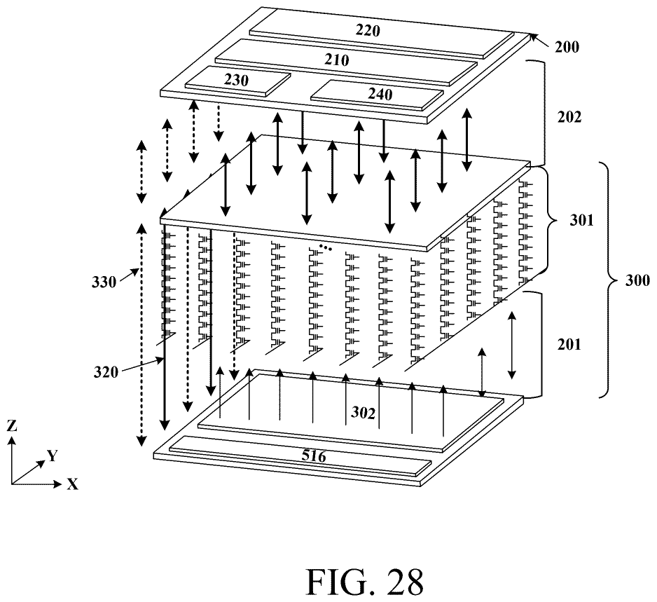

FIG. 28 is a structural schematic diagram of a semiconductor device provided by an example of the present disclosure.

According to a fourth aspect, referring to FIG. 28, an example of the present disclosure provides a semiconductor device including one or more of the following: any one of the semiconductor structures provided in the first aspect, any one of the semiconductor structures provided in the second aspect, or any one of the semiconductor structures provided in the third aspect; and a processing circuit is bonded to the semiconductor structure and configured to convert analog calculation information obtained by a first operation performed by the semiconductor structure into digital information and perform a second operation on the digital information, where the analog calculation information includes a first current passing through the memory string of the semiconductor structure.

Referring to FIG. 28, the semiconductor device includes a processing circuit 200 and a semiconductor structure 300; and the processing circuit 200 is bonded to the semiconductor structure 300.

In some examples, the processing circuit includes an analog-to-digital conversion circuit and a data processing circuit; the analog-to-digital conversion circuit is configured to convert the analog calculation information into digital information; and the data processing circuit is configured to perform a second operation on the digital information.

In some examples, the processing circuit 200 includes an analog-to-digital conversion circuit and a data processing circuit; the semiconductor structure 300 includes a memory array 301 for performing a first operation and at least part of the peripheral circuit 302 coupled to the memory array 301; the analog-to-digital conversion circuit is configured to convert analog calculation information obtained by performing the first operation on the memory array 301 into digital information; and the data processing circuit is configured to perform a second operation on the digital information.

In some examples, the processing circuit 200 and the semiconductor structure 300 are in different planes and stacked on each other. Also, the memory array 301 and the peripheral circuit 302 in the semiconductor structure 300 may be in different planes and stacked on each other, so that the planar size of the semiconductor device may be reduced.

In some examples, the processing circuit 200 and the semiconductor structure 300 may be formed in parallel on different substrates, such as forming the processing circuit 200 on the first substrate, forming the memory array 301 on the second substrate, and forming the peripheral circuit 302 on the third substrate, and then they are stacked with each other by various bonding techniques such as hybrid bonding, transfer bonding and the like. In some examples, the memory array 301 on the second substrate and the peripheral circuit 302 on the third substrate may be coupled through the first bonding layer 201 to obtain the semiconductor structure 300; and the semiconductor structure 300 and the processing circuit 200 on the first substrate may be coupled through the second bonding layer 202.

In the example of the present disclosure, by integrating the processing circuit 200 and the semiconductor structure 300 vertically, and separating the processing circuit 200, the memory array 301 and the peripheral circuit 302 vertically into different planes, the chip size may be reduced, and the storage density may be increased.

In an example of the present disclosure, the semiconductor structure 300 includes a first semiconductor structure formed with a memory array 301 and a second semiconductor structure formed with at least a portion of the peripheral circuit 302. In some examples, a portion of the peripheral circuit is formed in the second semiconductor structure and another portion is formed in the first semiconductor structure. In other words, the peripheral circuit of the memory array may be divided into two parts, one part and the memory array are formed together in the first semiconductor structure, and the other part is formed in the second semiconductor structure. In other examples, the peripheral circuits may all be formed in the second semiconductor structure. In the following examples, the peripheral circuits all formed in the second semiconductor structure are illustrated as an example for description.

In the example of the present disclosure, the semiconductor structure 300 further includes a first connection structure 320 extending through the memory array 301 and connected to the bit line and the second bonding layer, where the memory array 301 is connected to the analog-to-digital conversion circuit 210 through the bit line, the first connection structure 320, and the second bonding layer 202. In an example, the first connection structure 320 is a through-array contact (TAC). In some examples, one end of the first connection structure 320 is connected to the bit line, and the other end is connected to the second bonding layer. The bit line may be connected to the analog-to-digital conversion circuit 210 through the first connection structure 320 and the second bonding layer, so as to transmit the analog calculation information to the analog-to-digital conversion circuit 210.

In some examples, the processing circuit further includes a first interface circuit and a controller; the first interface circuit is configured to output an operation result of the second operation performed by the digital processing circuit to an external device; and the controller is configured to control the semiconductor structure to perform a first operation.

In some examples, the first operation includes a multiply-accumulate operation.

In an example of the present disclosure, the first interface circuit 230 is configured to receive and send data between the semiconductor device and another external device. In an example, the first interface circuit 230 is configured to output the operation result of the second operation performed by the data processing circuit 220 to the external device. The controller 240 may be configured to control operation of the processing circuit 200 and the semiconductor structure 300. That is, the controller 240 may serve as a memory controller that manages data storage and transmission in the semiconductor structure 300 and an operational controller that manages data operation and transmission in the processing circuit 200. In some examples, the controller 240 is further configured to control data transmission between the processing circuit 200 and the semiconductor structure 300. In some examples, the controller 240 is further configured to receive input data sent by the external device and send the input data to the semiconductor structure 300.

In some examples, the controller 240 is coupled to the semiconductor structure 300 and an external device (e.g., a host), and configured to control the semiconductor structure 300. The controller 240 may manage data stored in the semiconductor structure 300 and communicate with the external device.

In some examples, the controller 240 may also be configured to manage various functions with respect to data stored in or to be stored in the semiconductor structure 300, including, but not limited to, bad block management, garbage collection, logical-to-physical address translation, wear leveling, and the like. In some examples, the controller 240 is further configured to process an Error Correction Code (ECC) with respect to data read from or written to the semiconductor structure. In some examples, controller 240 may also perform any other suitable function, such as formatting a semiconductor structure.

In some examples, the first interface circuit 230 may be configured in the controller 240, and an interface protocol may be used for the first interface circuit between the controller 240 and an external device, such that the controller 240 may communicate with an external device through at least one of various interface protocols, such as a USB protocol, an MMC protocol, a Peripheral Component Interconnect (PCI) protocol, a PCI Express (PCI-E) protocol, an Advanced Technology Attachment (ATA) protocol, a Serial ATA protocol, a parallel ATA protocol, a Small Computer Small Interface (SCSI) protocol, an Enhanced Small Disk Interface (ESDI) protocol, an Integrated Drive Electronics (IDE) protocol, a Firewire protocol, or the like. The first interface circuit 230 herein may also be referred to as a front-end interface. In some examples, the controller 240 performs command or data interaction with the semiconductor structure 300 through a plurality of configured channels. These channels are also referred to as back-end interfaces.

In the example of the present disclosure, the semiconductor structure 300 further includes a fourth connection structure 330 extending through the memory array 301; one end of the fourth connection structure 330 is connected to the second semiconductor structure, and the other end is connected to the first interface circuit 230 through the second bonding layer 202. Therefore, the peripheral circuit 302 in the semiconductor structure may be connected to the first interface circuit 230 through the fourth connection structure 330, and perform data transmission with other external device through the first interface circuit 230.

It should be noted that the dotted arrow in FIG. 28 is the fourth connection structure 330, and the number of the dotted arrows is merely an example, and is not intended to limit the present disclosure. It should also be noted that the bonding layer (e.g., the second bonding layer 202 between the processing circuit 200 and the memory array 301) may further include an interconnection structure coupled to the fourth connection structure 330, so that the interconnection structure may connect the fourth connection structure 330 to the first interface circuit 230.

In the example of the present disclosure, the second semiconductor structure further includes a second interface circuit 516. For instance, the second semiconductor structure further includes a second interface circuit 516, and the semiconductor structure 300 is further connected to the processing circuit 200 through the second interface circuit 516. That is, the second interface circuit 516 herein may be an interface coupled to the back-end interface of the controller. That is, the second interface circuit 516 may be an interface for communication between the semiconductor structure and the processing circuit. The second interface circuit 516 may be coupled to the control logic 512 and serve as a control buffer to buffer and relay control commands received from a host (not shown) to the control logic 512, and buffer and relay status information received from the control logic 512 to the host. The second interface circuit 516 may also be coupled to the column decoder/bit line driver 506 via a data bus 518 and serve as a data I/O interface and a data buffer to buffer or relay data to or from the memory array 301.

In some examples, the data processing circuit 220 in the processing circuit 200 includes a processor that may include a special-purpose processor, e.g., such as a CPU, a GPU, a digital signal processor (DSP), a tensor processing unit (TPU), a visual processing unit (VPU), a neural processing unit (NPU), a synergistic processing unit (SPU), a physics processing unit (PPU), and an image signal processor (ISP). In an example, the data processing circuit is an NPU. The NPU may perform operations such as arithmetic or logical operation, rotation and shift operation, compensation operation, activation operation and pooling operation, and the like.

In some examples, the second operation includes one or more of compensation, activation, shift, or pooling operations.

In an example, the semiconductor structure in the semiconductor device is configured to store a weight matrix to perform a multiply-accumulate operation and output analog calculation information; the processing circuit in the semiconductor device is configured to convert the analog calculation information output by the semiconductor structure into digital information, and perform an activation operation on the digital information to obtain an output result. In some examples, the activation operation may be implemented by an activation function stored in the NPU, which may include, but is not limited to, an step function, a correction function, an sigmoid function, a hyperbolic tangent (tanh) function, and a softplus function (also referred to as smooth correction).

The semiconductor structure provided by an example of the present disclosure is similar to the semiconductor structure provided in the first aspect, the second aspect, and the third aspect, and for technical features not specifically disclosed in the examples of the present disclosure, reference may be made to the examples of the first aspect, the second aspect, and the third aspect, and details are not described herein again.

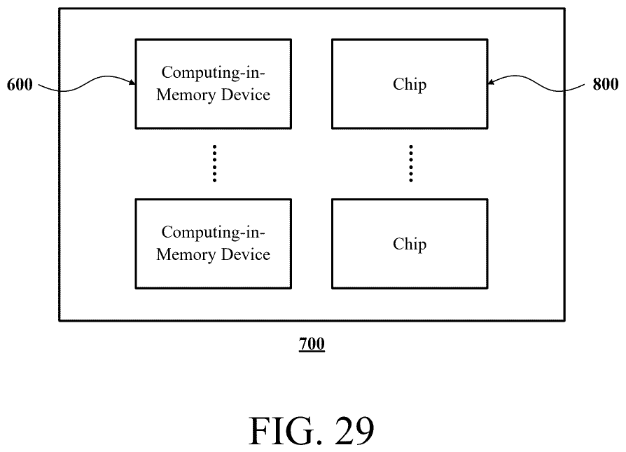

FIG. 29 is a schematic diagram of an example system having a computing-in-memory device provided by an example of the present disclosure. The system 700 may be a mobile phone, a desktop computer, a laptop computer, a tablet computer, a vehicle computer, a game console, a printer, a positioning device, a wearable electronic device, a smart sensor, a Virtual Reality (VR) device, an Augmented Reality (AR) device, or any other suitable electronic device having a computing-in-memory device therein. The system 700 may include one or more computing-in-memory devices 600, and one or more other types of chips 800. For example, the chip 800 includes, but is not limited to, a sensor chip, a memory chip, a logic chip, and the like. The one or more computing-in-memory devices 600 and one or more other types of chips 800 may be integrated in a package, such as a Printed Circuit Board (PCB) package. As such, the system 700 may be applied to different scenarios.

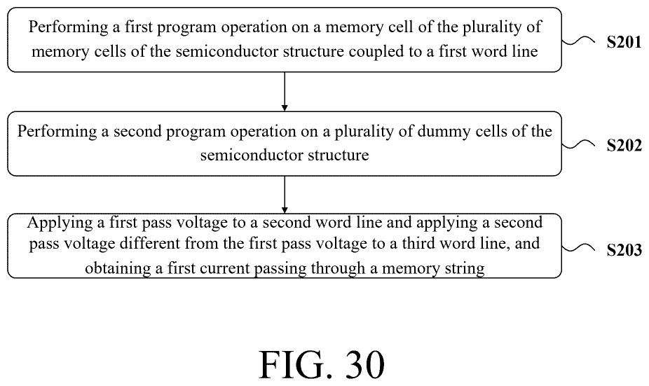

FIG. 30 is a schematic flowchart of a method of operating a semiconductor structure provided by an example of the present disclosure.

Referring to FIG. 30, the method may include operations S201, S202, and S203.

At operation S201, the method may include performing a first program operation on a memory cell of the plurality of memory cells of the semiconductor structure coupled to a first word line;

At operation S202, the method may include performing a second program operation on a plurality of dummy cells of the semiconductor structure;

At operation S203, the method may include applying a first pass voltage to a second word line and applying a second pass voltage different from the first pass voltage to a third word line, and obtaining a first current passing through a memory string.

The semiconductor structure includes a memory array configured to perform a first operation and a peripheral circuit coupled to the memory array; the memory array includes a memory string; a first end of the memory string is connected to a source line, and a second end of the memory string is connected to a bit line; the memory string includes a plurality of memory cells and a plurality of dummy cells; the plurality of memory cells includes a first memory cell and a second memory cell; the first word line is coupled to the first memory cell, the second word line is coupled to the second memory cell; and the third word line is coupled to the plurality of dummy memory cells.

In some examples, the method includes: completing the second program operation when the first current is less than a first preset value.

In some examples, the method includes: increasing a program voltage of the second program operation according to the first current being greater than or equal to the first preset value and continuing to perform a second program operation; and continuing to apply a first pass voltage to the second word line and apply a second pass voltage to the third word line to obtain a corresponding first current; and completing the second program operation when the first current is less than the first preset value.

In some examples, the method includes: applying a program voltage, during performing the first program operation, to the first word line by applying a plurality of first step pulse voltages; a difference between two adjacent ones of first step pulse voltages is a first step length voltage; applying a program voltage to the third word line by applying a plurality of second step pulse voltages during performing the second program operation; a difference between two adjacent second step pulse voltages is a second step length voltage, where a pulse width of the second step pulse voltage is less than a pulse width of the first step pulse voltage, or the second step length voltage is less than the first step length voltage.

In some examples, the method further includes: applying a read voltage to the first word line, applying a first pass voltage to the second word line, and applying a first operating voltage less than the second pass voltage to the third word line during performing a reading operation on the memory cell coupled with the first word line, such that the plurality of dummy cells operate in the linear region.

In some examples, the method further includes: performing a first program operation, where the memory cell coupled to the first word line has a first threshold voltage; performing a second program operation, where one of the plurality of dummy cells has a second threshold voltage that is greater than the first threshold voltage; applying a read voltage to the first word line, applying a first pass voltage to the second word line, and applying a second operating voltage to the third word line during performing a reading operation on the memory cell coupled to the first word line, where the second operating voltage is less than the first pass voltage.

In some examples, the method further includes: applying a read voltage to the first word line, applying a third pass voltage to the second word line, and applying a third operating voltage to the third word line during performing a first reading operation on the memory cell coupled with the first word line, according to the memory cell coupled with the first word line being at a first position in the memory string; applying a read voltage to the first word line, applying a fourth pass voltage to the second word line, and applying a third operating voltage to the third word line during performing a second reading operation on the memory cell coupled with the first word line, according to the memory cell coupled with the first word line being at a second position in the memory string, where the first position is closer to the bit line than the second position, and the third pass voltage is greater than the fourth pass voltage.

In some examples, the plurality of dummy cells include: a bottom dummy cell between the source line and the plurality of memory cells, or a top dummy cell between the bit line and the plurality of memory cells.

In some examples, the method further includes: performing a reading operation on corresponding memory cells located in the same column and coupled to the first word line, obtaining a second current passing through the bit line, and determining a result of the first operation based on the second current, where the plurality of memory strings located in the same column have a first end connected to the source line and a second end connected to the bit line, and the first word line is coupled to corresponding memory cells in a plurality of memory strings located in the same column.

In some examples, the third word line includes a first portion and a plurality of second portions connected to the first portion; a first end of each second portion is connected to a gate terminal of a corresponding dummy cell; and a second end of each second portion is commonly connected to the first portion, where the first portion is configured to receive the second pass voltage.

The semiconductor structure operated using the method described herein may be the same as or similar to the memory device in the examples of the first aspect, the second aspect, and the third aspect, and for technical features not specifically disclosed in the examples of the present disclosure, reference may be made to the semiconductor structure in the above-described examples of the first aspect, the second aspect, and the third aspect.

It should be understood that “one example” or “an example” mentioned throughout the specification means that a specific feature, structure, or characteristic related to the example is included in at least one example of the present disclosure. Thus, “in one example” or “in an example” mentioned throughout the specification need not necessarily refer to the same example. Further, these particular features, structures, or characteristics may be incorporated in one or more examples in any suitable manner. It should be understood that, in various examples of the present disclosure, the sequence numbers of the foregoing processes do not indicate a sequence of execution sequences, and an execution sequence of each process should be determined by using a function and an intrinsic logic thereof, and should not constitute any limitation on an implementation process of the examples of the present disclosure. The foregoing sequence numbers of the examples of the present disclosure are merely for description, and do not represent the advantage or disadvantage of the examples.

The above descriptions are only some examples of the present disclosure, and are not intended to limit the protection scope of the present disclosure. Any equivalent structural transformation or direct or indirect implementation according to the specification and accompanying drawings of the present disclosure is included within the protection scope of the present disclosure under the inventive concept of the present disclosure.

What is claimed is:

1. A semiconductor structure, comprising:
a memory array configured to perform a first operation, the memory array comprising:
a memory string, wherein a first end of the memory string is connected to a source line, a second end of the memory string is connected to a bit line, and the memory string comprises:
a plurality of memory cells and a plurality of dummy cells, wherein the plurality of memory cells comprise a first memory cell and a second memory cell, a first word line is coupled to the first memory cell, a second word line is coupled to the second memory cell, and a third word line is coupled to the plurality of dummy cells; and
a peripheral circuit coupled to the memory array and configured to:
perform a first program operation on the first memory cell;
perform a second program operation on the plurality of dummy cells;
apply a first pass voltage to the second word line;
apply a second pass voltage different from the first pass voltage to the third word line; and
obtain a first current passing through the memory string.

2. The semiconductor structure according to claim 1, wherein the peripheral circuit is configured to:
complete the second program operation when the first current is less than a first preset value.

3. The semiconductor structure according to claim 1, wherein the peripheral circuit is configured to:
increase a program voltage of the second program operation according to the first current being greater than or equal to a first preset value and continue to perform the second program operation;
continue to apply the first pass voltage to the second word line and apply the second pass voltage to the third word line to obtain a corresponding first current; and
complete the second program operation when the first current is less than the first preset value.

4. The semiconductor structure according to claim 1, wherein the peripheral circuit is configured to:
apply a program voltage, during performing the first program operation, to the first word line by applying a plurality of first step pulse voltages, wherein a difference between two adjacent ones of the first step pulse voltages is a first step length voltage; and
apply a program voltage, during performing the second program operation, to the third word line by applying a plurality of second step pulse voltages, wherein a difference between two adjacent ones of the second step pulse voltages is a second step length voltage,
wherein a pulse width of the second step pulse voltage is less than a pulse width of the first step pulse voltage, or the second step length voltage is less than the first step length voltage.

5. The semiconductor structure according to claim 1, wherein the peripheral circuit is further configured to:
apply a read voltage to the first word line, apply the first pass voltage to the second word line, and apply a first operating voltage less than the second pass voltage to the third word line during performing a reading operation on the memory cell coupled with the first word line, such that the plurality of dummy cells operate in a linear region.

6. The semiconductor structure according to claim 1, wherein the peripheral circuit is further configured to:
perform the first program operation, wherein the memory cell coupled to the first word line has a first threshold voltage;
perform the second program operation, wherein one of the plurality of dummy cells has a second threshold voltage that is greater than the first threshold voltage; and
apply a read voltage to the first word line, apply the first pass voltage to the second word line, and apply a second operating voltage to the third word line during performing a reading operation on the memory cell coupled with the first word line, wherein the second operating voltage is less than the first pass voltage.

7. The semiconductor structure according to claim 1, wherein the peripheral circuit is further configured to:
apply a read voltage to the first word line, apply a third pass voltage to the second word line, and apply a third operating voltage to the third word line during performing a first reading operation on the memory cell coupled with the first word line, according to the memory cell coupled with the first word line being at a first position in the memory string; and
apply the read voltage to the first word line, apply a fourth pass voltage to the second word line, and apply the third operating voltage to the third word line during performing a second reading operation on the memory cell coupled with the first word line, according to the memory cell coupled with the first word line being at a second position in the memory string,
wherein the first position is closer to the bit line than the second position, and the third pass voltage is greater than the fourth pass voltage.

8. The semiconductor structure according to claim 1, wherein the plurality of dummy cells comprise: a bottom dummy cell between the source line and the plurality of memory cells, or a top dummy cell between the bit line and the plurality of memory cells.

9. The semiconductor structure according to claim 1, wherein the memory string comprises a plurality of memory strings, the plurality of memory strings located in a same column have a first end connected to the source line and a second end connected to the bit line, the first word line is coupled to corresponding memory cells in the plurality of the memory strings located in the same column, and the peripheral circuit is further configured to:
perform a reading operation on the corresponding memory cells coupled to the first word line;
obtain a second current passing through the bit line; and
obtain a result of the first operation based on the second current.

10. The semiconductor structure according to claim 1, wherein the third word line comprises a first portion and a plurality of second portions connected to the first portion; a first end of each of the second portions is connected to a gate terminal of a corresponding one of the dummy cells; and a second end of each of the second portions is commonly connected to the first portion, and wherein the first portion is configured to receive the second pass voltage.

11. A semiconductor structure, comprising:
a stack structure comprising a gate layer and an insulating layer spaced apart with each other, wherein the gate layer comprises a plurality of gate layers, and the plurality of gate layers comprise a plurality of first gate layers and a plurality of second gate layers;
a memory structure extending through the stack structure, and comprising a plurality of memory cells coupled to the first gate layers and a plurality of dummy cells coupled to the second gate layers; and
a connection structure comprising a conductive material and being in contact with and electrically connected to the plurality of second gate layers.

12. The semiconductor structure according to claim 11, wherein the connection structure comprises:
a first connection line located over the stack structure;
a plurality of first contact structures with first ends extending and connected to the second gate layers, respectively, and second ends commonly connected to the first connection line; or
a second contact structure with a first end extending through at least some of the plurality of second gate layers and connected to the plurality of second gate layers and a second end connected to the first connection line.

13. The semiconductor structure according to claim 11, wherein the plurality of second gate layers comprise a bottom second gate layer located at bottom of the stack structure or a top second gate layer located at top of the stack structure.

14. A semiconductor device, comprising:
one or more or
one or more semiconductor structures each comprising:
a memory array configured to perform a first operation and a peripheral circuit coupled to the memory array, wherein the memory array comprises a memory string, a first end of the memory string is connected to a source line, a second end of the memory string is connected to a bit line, and the memory string comprises a plurality of memory cells and a plurality of dummy cells, and wherein
the plurality of memory cells are coupled to a plurality of first gate layers, the plurality of dummy cells are coupled to a plurality of second gate layers, first ends of the plurality of second gate layers are coupled to the plurality of dummy cells respectively, second ends of the plurality of second gate layers commonly contact and are electrically connected to a connection structure, and the connection structure comprises a conductive material; or
one or more semiconductor structures each comprising:
a stack structure comprising a gate layer and an insulating layer spaced apart with each other, wherein the gate layer comprises a plurality of gate layers, and the plurality of gate layers comprise a plurality of first gate layers and a plurality of second gate layers;
a memory structure extending through the stack structure, and comprising a plurality of memory cells coupled to the first gate layers and a plurality of dummy cells coupled to the second gate layers; and
a connection structure comprising a conductive material and being in contact with and electrically connected to the plurality of second gate layers; and
a processing circuit connected to the semiconductor structure and configured to:
convert analog calculation information obtained by the first operation performed by the semiconductor structure into digital information; and
perform a second operation on the digital information,
wherein the analog calculation information comprises a first current passing through the memory string of the semiconductor structure.

15. The semiconductor device according to claim 14, wherein the processing circuit comprises:
an analog-to-digital conversion circuit configured to convert the analog calculation information into the digital information; and
a data processing circuit configured to perform the second operation on the digital information.

16. The semiconductor device according to claim 15, wherein the processing circuit further comprises:
a first interface circuit configured to output an operation result of the second operation performed by the digital processing circuit to an external device; and
a controller configured to control the semiconductor structure to perform the first operation.

17. The semiconductor device according to claim 14, wherein the first operation comprises a multiply-accumulate operation.

18. The semiconductor device according to claim 14, wherein the second operation comprises one or more of compensation, activation, shift, or pooling operations.

19. The semiconductor device according to claim 14, wherein the semiconductor structure comprising:
a memory array configured to perform a first operation, the memory array comprising:
a memory string, wherein a first end of the memory string is connected to a source line, a second end of the memory string is connected to a bit line, and the memory string comprises:
a plurality of memory cells and a plurality of dummy cells, wherein the plurality of memory cells comprise a first memory cell and a second memory cell, a first word line is coupled to the first memory cell, a second word line is coupled to the second memory cell, and a third word line is coupled to the plurality of dummy cells; and
a peripheral circuit coupled to the memory array and configured to:
perform a first program operation on the first memory cell;
perform a second program operation on the plurality of dummy cells;
apply a first pass voltage to the second word line;
apply a second pass voltage different from the first pass voltage to the third word line; and
obtain a first current passing through the memory string.

20. The semiconductor device according to claim 19, wherein the peripheral circuit is further configured to:
increase a program voltage of the second program operation according to the first current being greater than or equal to a first preset value and continue to perform the second program operation;
continue to apply the first pass voltage to the second word line and apply the second pass voltage to the third word line to obtain a corresponding first current; and
complete the second program operation when the first current is less than the first preset value.
